(19) United States
(12) Patent Application Publication
(10) Pub. No.: US 2025/0023549 A1
(43) Pub. Date: Jan. 16, 2025

(54) PIEZOELECTRIC VIBRATION ELEMENT AND PIEZOELECTRIC DEVICE

(71) Applicant: KYOCERA Corporation, Kyoto-shi, Kyoto (JP)

(72) Inventors: Masahiko GOTO, Tendo-shi (JP); Tomoki MURAYAMA, Higashine-shi (JP); Shohei UCHIDA, Higashine-shi (JP); Hiroyuki ISHIKAWA, Higashine-shi (JP)

(73) Assignee: KYOCERA Corporation, Kyoto-shi, Kyoto (JP)

(21) Appl. No.: 18/709,618

(22) PCT Filed: Nov. 29, 2022
(86) PCT No.: PCT/JP2022/043912

§ 371 Date: May 13, 2024

(30) Foreign Application Priority Data
Nov. 30, 2021 (JP) 2021-194001

(51) Int. Cl. H03H 9/19; H03H 9/125

(52) U.S. Cl. CPC H03H 9/19; H03H 9/125

(57) ABSTRACT

A piezoelectric blank of a piezoelectric vibration element includes a vibration portion and a fixation portion including different regions in plan view. A third surface of the fixation portion on a first side is higher than a first surface of the vibration portion on the first side in a direction of the first side. An excitation electrode overlies the first surface. An extension electrode is extended from the excitation electrode and overlies the third surface. The piezoelectric blank includes a recess recessed from the third surface toward a second side opposite to the first side. The recess has a shape in plan view in which an edge portion of the third surface on a first surface side is cut in. The extension electrode includes a portion extending from the first surface via the recess to the third surface.

### TECHNICAL FIELD

The present disclosure relates to a piezoelectric vibration element and a piezoelectric device.

### BACKGROUND OF INVENTION

For example, quartz crystal vibration elements and quartz crystal oscillators are known as piezoelectric devices. These piezoelectric devices include a piezoelectric vibration element that vibrates when an AC voltage is applied. A piezoelectric vibration element includes, for example, a plate-shaped piezoelectric blank (for example, a quartz crystal blank), a pair of excitation electrodes located on a pair of main surfaces (the largest surfaces of the plate shape, the front and back sides of the plate shape. The same and/or a similar definition applies to the following.) of the piezoelectric blank, and a pair of extension electrodes extended from the pair of excitation electrodes. The pair of extension electrodes are joined to, for example, pads of a package with a conductive joining material. Thus, the piezoelectric vibration element is mounted onto the package. By applying an AC voltage to the pair of extension electrodes, the AC voltage is applied to the piezoelectric blank through the pair of excitation electrodes.

Patent Literature 1 discloses a piezoelectric blank including a vibration portion and a fixation portion including different regions in plan view. The vibration portion is, for example, a portion including a pair of excitation electrodes and has a plate shape. The fixation portion is, for example, a portion including a pair of extension electrodes and is thicker than the vibration portion. In Patent Literature 1, the piezoelectric blank also includes recesses at an edge portion of the fixation portion on a vibration portion side. The extension electrodes extend from the vibration portion to the fixation portion via the recesses mentioned above.

### CITATION LIST

### Patent Literature

Patent Literature 1: Japanese Unexamined Patent Application Publication No. 2020-191579

### SUMMARY

In an aspect of the present disclosure, a piezoelectric vibration element includes a piezoelectric blank, a first excitation electrode, and a first extension electrode. The piezoelectric blank includes a vibration portion and a fixation portion including different regions in plan view. The vibration portion includes a first surface facing a first side and a second surface facing a second side opposite to the first side. The fixation portion includes a third surface facing the first side and a fourth surface facing the second side. The third surface is higher than the first surface in a direction of the first side. The first excitation electrode overlies the first surface. The first extension electrode is extended from the first excitation electrode and overlies the third surface. The piezoelectric blank includes a first recess recessed from the third surface toward the second side. The first recess has a shape in plan view in which a first edge portion of the third surface on a first surface side is cut in. The first extension electrode includes a portion extending from the first surface via the first recess to the third surface.

In an example, the first edge portion includes a first partial edge portion and a second partial edge portion. The first partial edge portion is located on one side of the vibration portion in a first direction in plan view. The second partial edge portion is located on one side of the vibration portion in a second direction orthogonal to the first direction in plan view and, along with the first partial edge portion, forms a recessed corner. The first recess has a shape in which at least one of the first partial edge portion and the second partial edge portion is cut in at the recessed corner.

In an example, when the size of the first recess in a direction parallel to the first edge portion is referred to as width of the first recess, a side surface of the first recess intersecting the first edge portion in plan view includes an inclined surface inclined in an orientation in which the width of the first recess increases toward the first side and extending from a bottom portion of the first recess to the third surface. The first extension electrode includes a portion extending from the bottom portion of the first recess via the inclined surface to the third surface.

In an aspect of the present disclosure, a piezoelectric device includes: the piezoelectric vibration element described above; and a package on which the piezoelectric vibration element is mounted.

### BRIEF DESCRIPTION OF THE DRAWINGS

FIG. 1 is a perspective view of a quartz crystal vibration element according to a first embodiment.

FIG. 2 is an enlarged plan view of region II in FIG. 1.

FIG. 3 is an enlarged plan view of region III in FIG. 2.

FIG. 4 is a cross-sectional view taken along line IV-IV in FIG. 3.

FIG. 5 is a cross-sectional view taken along line V-V in FIG. 3.

FIG. 6 is a perspective view of an application example of the quartz crystal vibration element in FIG. 1.

FIG. 7 is a cross-sectional view taken along line VII-VII in FIG. 6.

FIG. 8 is a plan view of another example of an extension electrode and a recess.

FIG. 9A is a schematic plan view of another example of the position of a fixation portion.

FIG. 9B is a schematic plan view of still another example of the position of a fixation portion.

FIG. 10 is a cross-sectional view of an example of the thickness of the fixation portion.

FIG. 11 is a perspective view of a quartz crystal vibration element according to a second embodiment.

FIG. 12 is a cross-sectional view taken along line XII-XII in FIG. 12.

### DESCRIPTION OF EMBODIMENTS

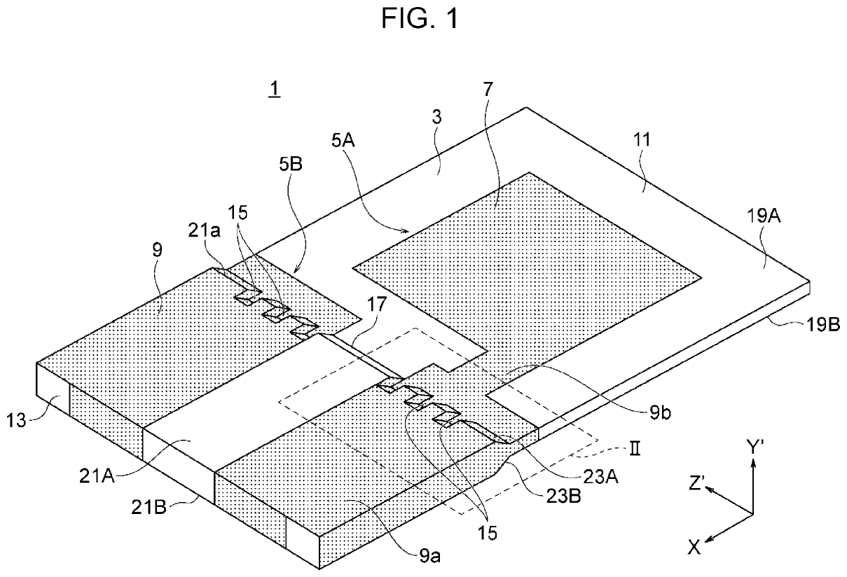

Hereinafter, a quartz crystal vibration element (which is sometimes simply referred to as “quartz crystal element”) according to an embodiment will be described with reference to the drawings. Note that the figures used in the following description are schematic, and hence, the ratios of dimensions and the like on the drawings are not necessarily the same as those in actuality. Also, the ratios of dimensions and the like are not necessarily the same between the drawings. Plan view refers to viewing in the direction parallel to the Y′ direction of the XY′Z′ coordinate system indicated in FIG. 1 and other figures, unless otherwise noted.

### (Overview of Quartz Crystal Element)

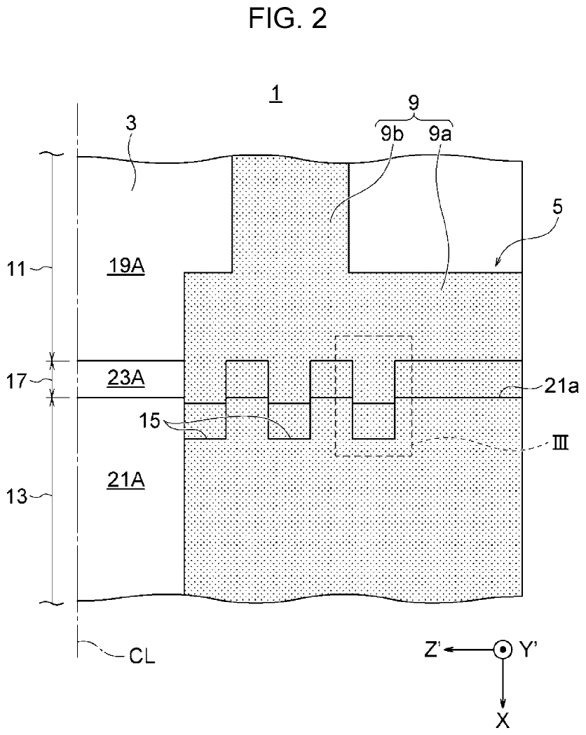

FIG. 1 is a perspective view of a quartz crystal element 1 according to an embodiment (more specifically, a first embodiment). FIG. 2 is an enlarged plan view of region II in FIG. 1. Note that the quartz crystal element 1 is, for example, approximately 180-degree rotationally symmetric with respect to a center line CL (FIG. 2) parallel to the X axis. Hence, the perspective view of the quartz crystal element 1 from the −Y′ side is the same as and/or similar to that of FIG. 1.

The quartz crystal element 1 is, for example, configured to generate vibration when receiving an AC voltage. This vibration is used, for example, to generate an oscillation signal the signal strength (for example, voltage and/or current) of which oscillates at a constant frequency. In other words, the quartz crystal element 1 is included, for example, in a quartz crystal vibrator or a quartz crystal oscillator.

The quartz crystal element 1 includes a quartz crystal blank 3 and first and second conductor patterns 5A and 5B (which are hereinafter referred to as “conductor patterns 5” and are sometimes not distinguished from each other) that overlie the quartz crystal blank 3. The two conductor patterns 5 are not short-circuited to each other. Each conductor pattern 5 includes an excitation electrode 7 and an extension electrode 9 extended from the excitation electrode 7. In other words, the quartz crystal element 1 includes a pair of excitation electrodes 7 and a pair of extension electrodes 9 coupled to the pair of excitation electrodes 7.

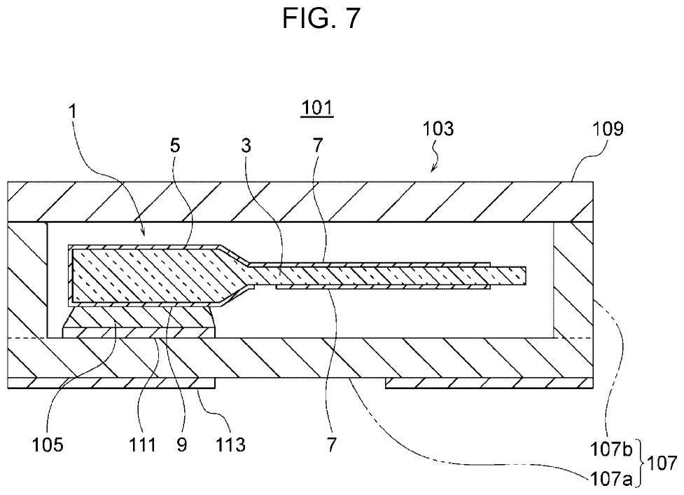

The pair of extension electrodes 9 contribute to mounting the quartz crystal element 1. Specifically, as illustrated in FIG. 7 described later, the quartz crystal element 1 is mounted on a package 103, for example, by joining the extension electrodes 9 to pads 111 of the package 103 with bumps 105 composed of a conductive joining material. Note that although the quartz crystal element 1 may be mounted on a member (for example, a circuit substrate) other than the package 103, the description of the embodiment is sometimes expressed, for convenience, on the assumption that the quartz crystal element 1 is mounted on the package 103. When an AC voltage is applied to the pair of extension electrodes 9 via the package 103, the AC voltage (electric field) is applied to the quartz crystal blank 3 through the pair of excitation electrodes 7. Thus, the quartz crystal blank vibrates.

The quartz crystal blank 3 includes an vibration portion 11 configured to be excited through the pair of excitation electrodes 7 and a fixation portion 13 configured to be fixed to the package 103 with the pair of extension electrodes 9 interposed therebetween. The fixation portion 13 is thicker than the vibration portion 11. This configuration, for example, enables the vibration portion 11 to be thin enough to vibrate at high frequency while the fixation portion 13 ensures a sufficient strength of the quartz crystal blank 3.

The quartz crystal blank 3 includes one or more (in the illustrated example, a plurality of) recesses 15 recessed from the surfaces of the fixation portion 13 on the +Y′ side and the −Y′ side. The recesses 15 have a shape in plan view in which an edge portion 21a of the fixation portion 13 on the vibration portion 11 side is cut in. The extension electrode 9 includes a portion extending from the surface of the vibration portion 11 via the recesses 15 to the surface of the fixation portion 13. Note that although edge portions of the recesses 15 are a kind of edge portion of the fixation portion 13, the following description is based on the assumption that the term “the edge portion (the edge portion 21a) of the fixation portion 13” does not include the edge portions of the recesses 15, unless otherwise noted, or unless a contradiction or the like occurs.

The recesses 15 as mentioned above provide various effects described in detail later. For example, the recesses 15 improve the reliability of the electrical continuity of the extension electrode 9 at a step between the fixation portion 13 and the vibration portion 11. The reason is described later.

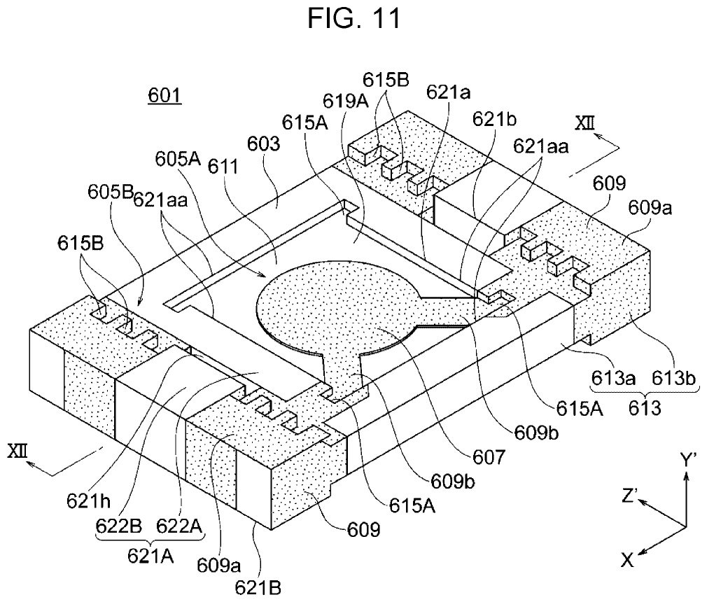

The specific configuration of the recesses 15 can be determined as appropriate. The recesses 15 in the present embodiment include, for example, new configurations as follows.
The recesses 15 are located at recessed corners of the vibration portion 11 (recesses 615A in FIG. 11 described later).
Of the side surfaces of the recess 15, a first side surface 15b (described later) intersecting the edge portion 21a includes a crystal plane.
The first side surface 15b is inclined relative to a thickness direction (Y′ direction) of the quartz crystal blank 3.
The width of the recess 15 (the length in the Z′ direction) is larger than the dimensions of specified portions.
The horizontal depth of the recess 15 in plan view (the length in the X direction) is larger than the dimensions of specified portions.
The bottom surface 15a (described later) of the recess 15 protrudes into the fixation portion 13 in plan view. Note that this seems natural from the above description. An example of a configuration not included in the configuration mentioned above is one in which a third side surface 15d (described later) of the recess 15 on the horizontally deeper side (on the +X side, in the illustrated example) in plan view is inclined such that the further toward the vibration portion 11 side (the −X side) from the horizontally deeper side (the +X side), the lower and extends toward the vibration portion 11 side to the edge portion 21a of the fixation portion 13 on the vibration portion 11 side (this configuration may also be included in the technology according to the present disclosure).

Because the recesses 15 according to the embodiment include a configuration as above, the recesses 15 provide various effects as described in detail later. One of the examples is that the effect of improving the reliability of the electrical continuity of the extension electrode 9 as described above increases. The reason is described later.

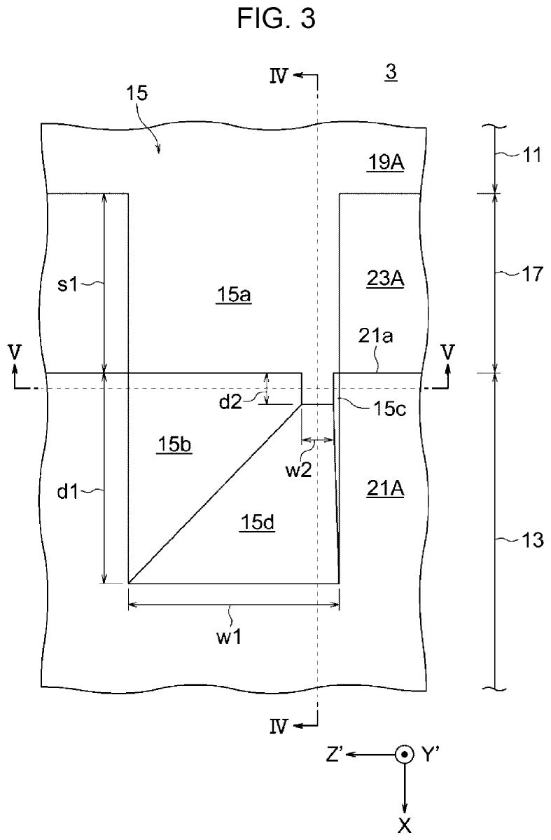

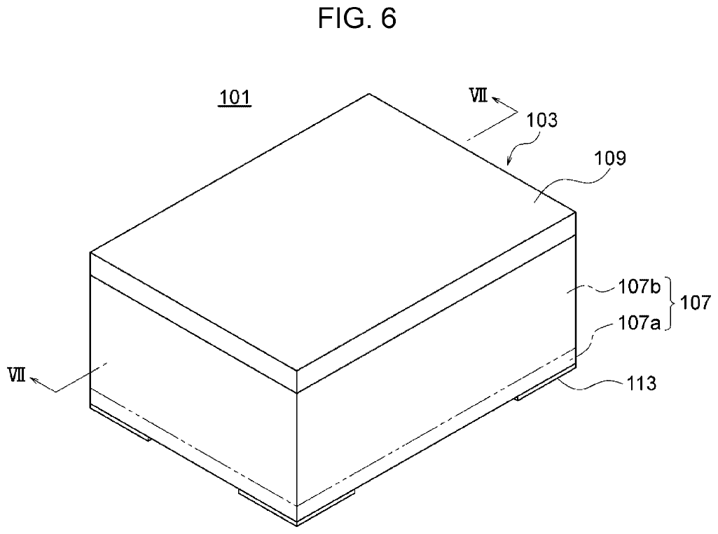

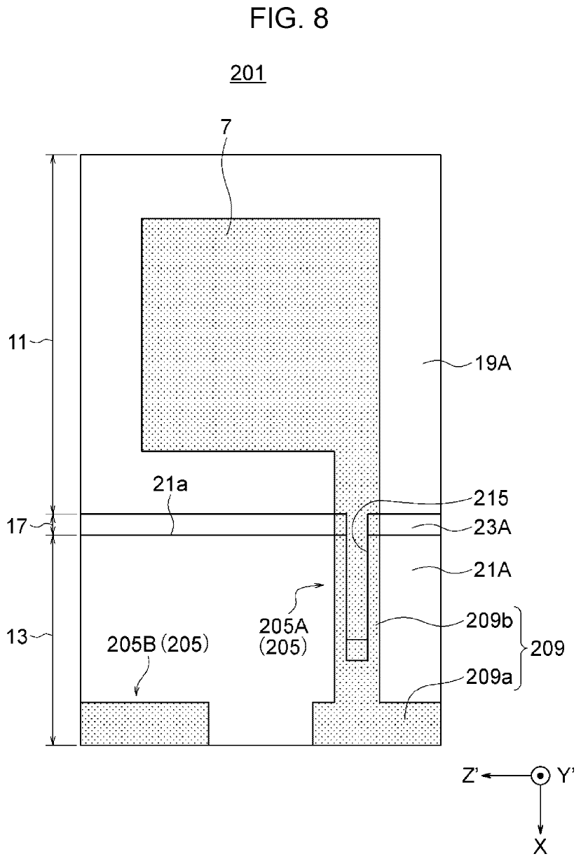

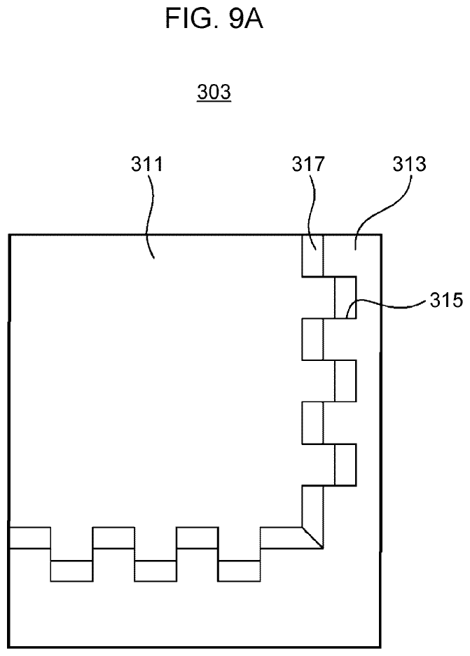

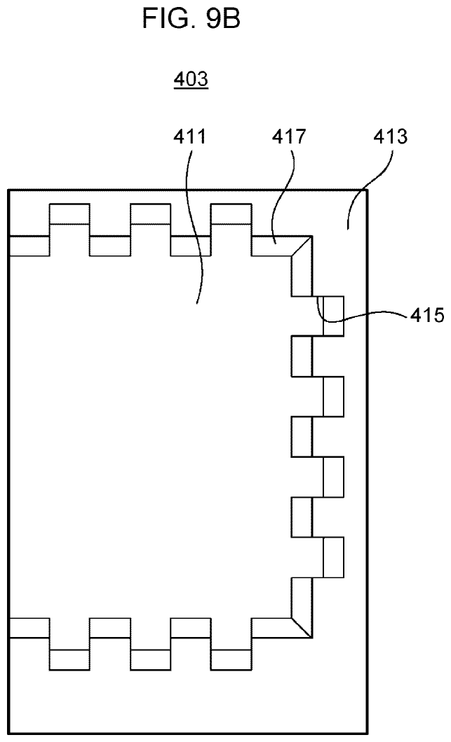

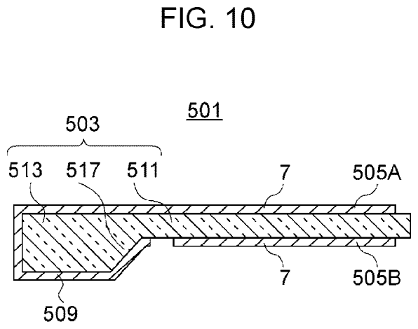

Hereinafter, description will be made approximately in the following order.
Chapter 1 First Embodiment
   1. Quartz Crystal Element 1 (FIGS. 1 and 2)
      1.1. Quartz Crystal Blank 3 (Configurations other than Recess 15)
         1.1.1. Vibration Portion 11
         1.1.2. Fixation Portion 13
         1.1.3. Intermediate Portion 17 (Portion between Vibration Portion 11 and Fixation Portion 13)
      1.2. Conductor Pattern 5
         1.2.1. Excitation Electrode 7
         1.2.2. Extension Electrode 9
      1.3. Recess 15 (FIGS. 3 to 5)
         1.3.1. Outline of Recess 15
         1.3.2. Specific Example (illustrated Example) of Shape and Dimensions of Recess 15
      1.4. Overlap between Extension Electrode 9 and Recess 15
      1.5. Method of Manufacturing Quartz Crystal Element 1
      1.6. Summary of Quartz Crystal Element 1
   2. Application Example of Quartz Crystal Element 1 (FIGS. 6 and 7)
   3. Other Examples
      3.1. Another Example of Extension Electrode and Recess (FIG. 8)
      3.2. Another Example of Position of Fixation Portion (FIGS. 9A and 9B)
      3.3. Another Example of Thickness of Fixation Portion (FIG. 10)
Chapter 2 Second Embodiment
   1. Overview of Quartz Crystal Element
   2. Quartz Crystal Blank
      2.1. Whole Quartz Crystal Blank and Vibration Portion
      2.2. Fixation Portion
      2.3. Other Information
   3. Conductor Pattern
   4. Recess
   5. Method of Manufacturing Quartz Crystal Element
   6. Summary of Quartz Crystal Element

### Chapter 1 First Embodiment

### 1. Quartz Crystal Element

The quartz crystal element 1 is, for example, a so-called AT-cut quartz crystal vibration element. Specifically, the quartz crystal blank 3 is an AT-cut quartz crystal piece. The pair of excitation electrodes 7 overlie both sides of the quartz crystal blank 3 (more specifically, the vibration portion 11). When a voltage is applied to the vibration portion 11 in a thickness direction through the pair of excitation electrodes 7, so-called thickness-shear vibration occurs in the vibration portion 11. The resonant frequency of this vibration (in other words, the oscillation frequency) is basically determined by the thickness of the vibration portion 11. The quartz crystal element 1 may use a fundamental wave mode or use an overtone mode. The present embodiment is sometimes described based on an example of a configuration using the fundamental wave mode.

Various dimensions of the quartz crystal element 1 (the quartz crystal blank 3) may be determined as appropriate. The following illustrates examples of the ranges of dimensions. The length of the quartz crystal blank 3 in the X direction may be 500 μm or more and 1500 μm or less. The length of the quartz crystal blank 3 (the vibration portion 11, the fixation portion 13, and/or an intermediate portion 17) in the Z′ direction may be 300 μm or more and 800 μm or less. The length of the vibration portion 11 in the X direction may be 250 μm or more and 1150 μm or less (but is shorter than the length of the quartz crystal blank 3 in the X direction). The thickness of the vibration portion 11 may be 16 μm or less. When the fundamental wave vibration of thickness-shear vibration of an AT-cut plate is used, this thickness corresponds to frequencies of approximately 100 MHz or more. The length of the fixation portion 13 in the X direction may be 100 μm or more and 500 μm or less (but is shorter than the length of the quartz crystal blank 3 in the X direction). The thickness of the fixation portion 13 may be 50 μm or less.

### (1.1. Quartz Crystal Blank)

As described above, the quartz crystal blank 3 is, for example, an AT-cut quartz crystal piece. Specifically, when the Cartesian coordinate system XYZ consisting of the X axis (electrical axis), the Y axis (mechanical axis), and the Z axis (optical axis) in quartz crystal is rotated around the X axis by 30° or more and 50° or less (for example, 35° 15′) to define the Cartesian coordinate system XY′Z′, the quartz crystal blank 3 has a plate shape and includes a pair of main surfaces basically parallel to the XZ′ plane.

The correspondence relationship between the positive-negative direction of the X axis and the configuration of the quartz crystal element 1 (in another viewpoint, the shape of the quartz crystal blank 3) may be opposite to the one in the illustration. However, the description of the embodiment is made sometimes based on the illustrated correspondence relationship.

The planar shape of the quartz crystal blank 3 may be determined as appropriate. In the illustrated example, the planar shape of the quartz crystal blank 3 is a rectangular shape including the sides parallel to the Z′ axis and the X axis. Examples of other planar shapes of the quartz crystal blank 3 include a circular shape and an elliptical shape. Examples of other planar shapes also include a shape formed by swelling outside at least one of the four sides of a rectangle into a curved shape (for example, a circular arc).

Note that examples of rectangles include a square and a rectangle in a narrow sense. The term “rectangle” or “rectangular” mentioned here is not limited to a square or a rectangle in a strict sense and includes ones with chamfered corners, unless otherwise noted. The same and/or a similar definition applies to the description of shapes other than the planar shape of the quartz crystal blank 3.

In the planar shape of the quartz crystal blank 3, the X direction (the direction in which the main surfaces relatively shear in the thickness-shear vibration) may be the longitudinal direction (the illustrated example), the Z′ direction may be the longitudinal direction, or the length in the Z′ direction and the length in the X direction may be the same and/or similar. In the illustrated example, the longitudinal direction of the quartz crystal blank 3 is the X direction. In other words, the quartz crystal blank 3 includes the long sides parallel to the X axis and the short sides parallel to the Z′ axis.

The quartz crystal blank 3 may be fabricated by, for example, etching quartz crystal. In this case, due to the anisotropy of quartz crystal in etching, the side surfaces of various portions of the quartz crystal blank 3 may include inclined surfaces (in another viewpoint, crystal planes). However, in the description of the present embodiment, illustration of such inclined surfaces is sometimes omitted, and shapes and dimensions are sometimes described without considering the presence of inclined surfaces. In this case, the correspondence relationship between the shape and dimensions of the quartz crystal blank 3 illustrated as an example in the description of the embodiment and the actual shape and dimensions of the quartz crystal blank 3 with inclined surfaces may be judged rationally in consideration of the characteristics and the like of the quartz crystal element 1. For example, when the side surfaces of the quartz crystal blank 3 (or its various portions) include inclined surfaces, which causes a positional deviation between the main surface on the +Y′ side and the main surface on the −Y′ side in the XZ′ plane, it can be construed that description of the shape and dimensions of the quartz crystal blank 3 (or its various portions) is based on the maximum shape and dimensions in transparent plan view, although it depends on the direction of the positional deviation.

As described above, the quartz crystal blank 3 includes the vibration portion 11 and the fixation portion 13 including different regions in plan view and the thicknesses of which differ. The quartz crystal blank 3 also includes the intermediate portion 17 which is a region between the vibration portion 11 and the fixation portion 13 in plan view. The thickness of the intermediate portion 17 increases toward the fixation portion 13. The following describes these portions.

### (1.1.1. Vibration Portion)

The vibration portion 11 includes at least an inner region of the quartz crystal blank 3 in plan view. The inner region mentioned here refers to a region away from the outer edges of the quartz crystal blank 3. More specifically, for example, the vibration portion 11 may include a region including the centroid (center) of the quartz crystal blank 3 in plan view. Only for confirmation, the centroid is the point at which the cross-sectional first moment of any axis passing through the point is zero.

The planar shape, dimensions, and the like of the vibration portion 11 may be determined as appropriate. In the illustrated example, the planar shape of the vibration portion 11 has a rectangular shape including the sides parallel to the Z′ axis and the X axis. Examples of other planar shapes for the vibration portion 11 include a circular shape and an elliptical shape. Examples of other planar shapes also include a shape formed by swelling outside one or more of the four sides of a rectangle into a curved shape (for example, a circular arc). In the planar shape of the vibration portion 11, the X direction (the direction in which the main surfaces relatively shear in the thickness-shear vibration) may be the longitudinal direction, the Z′ direction may be the longitudinal direction, or the length in the Z′ direction and the length in the X direction may be the same and/or similar (the illustrated example).

The vibration portion 11 occupies, for example, a relatively large portion of the area (the area in transparent plan view) of the quartz crystal blank 3. For example, the vibration portion 11 occupies half or more of the area of the quartz crystal blank 3. However, a configuration in which the vibration portion 11 occupies only less than half of the area of the quartz crystal blank 3 is possible.

The vibration portion 11 has a plate shape parallel to the XZ′ plane and includes the main surfaces (a first surface 19A and a second surface 19B) parallel to the XZ′ plane. The first surface 19A faces the +Y′ side (one side in the thickness direction of the quartz crystal blank 3) and is orthogonal to the Y′ axis (the thickness direction). The second surface 19B faces the −Y′ side (the other side in the thickness direction of the quartz crystal blank 3) and is orthogonal to the Y′ axis (the thickness direction). In another viewpoint, the first surface 19A and the second surface 19B are parallel to each other.

### (1.1.2. Fixation Portion)

The fixation portion 13 includes at least part of the outer peripheral region of the quartz crystal blank 3 in plan view. In another viewpoint, the fixation portion 13 is adjacent to at least part of the outer edge of the vibration portion 11 with the intermediate portion 17 interposed therebetween. The length of the portion flanked by the fixation portion 13 and the outer edge of the vibration portion 11 (the length of the portion of the fixation portion 13 alongside the outer edge of the vibration portion 11) may be determined as appropriate, as can be understood from other examples described later (FIGS. 9A and 9B). In the illustrated example, the fixation portion 13 is adjacent to the vibration portion 11, alongside one side of the vibration portion 11 having a rectangular shape.

The direction in which the fixation portion 13 and the vibration portion 11 are adjacent to each other with the intermediate portion 17 interposed therebetween may be the X direction (the direction in which the main surfaces relatively shear in the thickness-shear vibration) (the illustrated example) or may be the Z′ direction. In another viewpoint, the adjacent direction mentioned above may be the lateral direction of the vibration portion 11 or the longitudinal direction of the vibration portion 11, or a configuration in which such distinguishing cannot be made is also possible (the illustrated example). In addition, the relationship between the adjacent direction mentioned above and the longitudinal direction of the quartz crystal blank 3 is not particularly limited.

The planar shape (the recesses 15 are not taken into account in this paragraph), dimensions, and the like of the fixation portion 13 may be determined as appropriate. For example, the fixation portion 13 may have a shape that has a fixed width and extends along an outer edge of the vibration portion 11 (the illustrated example) or may have such a shape that the shape of the edge portion on the vibration portion 11 side differs from the shape of the edge portion on the side opposite to the vibration portion 11. In the illustrated example, the fixation portion 13 has a rectangular shape and includes long sides parallel to one side of the vibration portion 11.

In the direction (the Z′ direction, in the illustrated example) orthogonal to the direction in which the fixation portion 13 and the vibration portion 11 are adjacent to each other with the intermediate portion 17 interposed therebetween, the fixation portion 13 may have a size the same as and/or similar to that of the vibration portion 11 (the illustrated example) or may be smaller than or larger than the vibration portion 11. The fixation portion 13 may have any length in the adjacent direction mentioned above (the X direction, in the illustrated example). In the illustrated example, the length of the fixation portion 13 in the X direction is shorter than the length of the vibration portion 11 in the X direction.

The fixation portion 13 has, for example, a flat plate shape parallel to the XZ′ plane, as with the vibration portion 11. However, the fixation portion 13 may have a shape not having a size that appears to be a plate shape. The fixation portion 13 includes main surfaces (a third surface 21A and a fourth surface 21B) parallel to the XZ′ plane, as with the vibration portion 11. The third surface 21A faces the +Y′ direction (one side in the thickness direction of the quartz crystal blank 3) and is orthogonal to the Y′ axis (the thickness direction). The fourth surface 21B faces the −Y′ direction (the other side in the thickness direction of the quartz crystal blank 3) and is orthogonal to the Y′ axis (the thickness direction). In another viewpoint, the third surface 21A and the fourth surface 21B are parallel to each other. In still another viewpoint, the third surface 21A and the fourth surface 21B are parallel to the first surface 19A and the second surface 19B.

The fixation portion 13 is thicker than the vibration portion 11 as described above. More specifically, the fixation portion 13 is higher than the vibration portion 11 on both sides in the thickness direction (Y′ direction). In another viewpoint, the third surface 21A facing one side (the +Y′ side) in the thickness direction is located further toward the one side than the first surface 19A facing the one side. The fourth surface 21B facing the other side (the −Y′ side) in the thickness direction is located further toward the other side than the second surface 19B facing the other side.

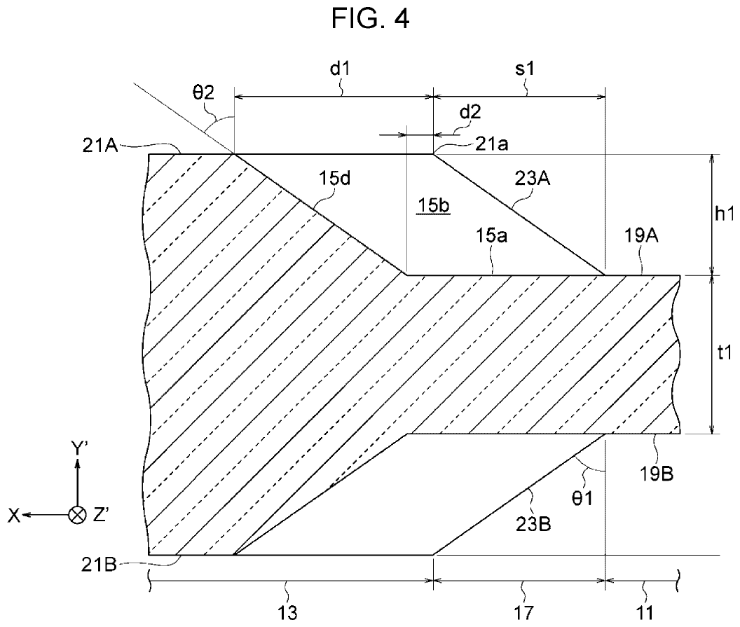

In terms of the height h1 (the symbol is indicated in FIG. 4) from the first surface 19A to the third surface 21A and the height from the second surface 19B to the fourth surface 21B, one of the heights may be larger than the other or may be the same and/or similar. Note that the present embodiment is based on an example of a configuration in which the two heights are the same and/or similar. These heights h1 may be smaller than, the same as and/or similar to, or larger than the thickness t1 (the symbol is indicated in FIG. 4) of the vibration portion 11.

### (1.1.3. Intermediate Portion)

The intermediate portion 17 extends, for example, approximately across the entire edge portion of the vibration portion 11 on the fixation portion 13 side and/or the entire edge portion 21a of the fixation portion 13 on the vibration portion 11 side. The dimensions of the intermediate portion 17 in plan view may be determined as appropriate. For example, in the direction (the Z′ direction, in the illustrated example) orthogonal to the direction in which the fixation portion 13 and the vibration portion 11 are adjacent to each other with the intermediate portion 17 interposed therebetween, the intermediate portion 17 may have a size the same as and/or similar to that of the vibration portion 11 and/or that of the fixation portion 13 (the illustrated example) or may be smaller than or larger than the vibration portion 11 and/or the fixation portion 13. The intermediate portion 17 may have any length in the adjacent direction mentioned above (the X direction, in the illustrated example). In the illustrated example, the length of the intermediate portion 17 in the X direction is shorter than the length of the fixation portion 13 in the X direction.

The thickness of the intermediate portion 17 increases toward the fixation portion 13 as described above. Specifically, the intermediate portion 17 includes a fifth surface 23A and a sixth surface 23B inclined such that the thickness of the intermediate portion 17 increases toward the fixation portion 13. The fifth surface 23A faces one side (the +Y′ side) in the thickness direction and is inclined relative to the first surface 19A in such an orientation that the fixation portion 13 side is located further toward the one side than the vibration portion 11 side. The sixth surface 23B faces the other side (the −Y′ side) in the thickness direction and is inclined relative to the second surface 19B in such an orientation that the fixation portion 13 side is located further toward the other side than the vibration portion 11 side. Each of the fifth surface 23A and the sixth surface 23B nearly consists of, for example, one plane.

The inclination angles of the fifth surface 23A and the sixth surface 23B may be the same as or different from each other. When they are the same, the way in which vibration leaked and propagating from the portion of the vibration portion 11 flanked between the pair of excitation electrodes 7 is reflected on the inclined portions of the intermediate portion 17 can be the same between an upper surface side and a lower surface side. Note that the description of the present embodiment is based on an example of a configuration in which the inclination angles are the same. Specific values for these inclination angles may be determined as appropriate. For example, as illustrated in FIG. 4 described later, θ1 is defined as the angle of the fifth surface 23A or the sixth surface 23B relative to the normal line (in another viewpoint, the Y′ axis) of the main surfaces of the fixation portion 13 or the vibration portion 11. The angle θ1 may be smaller than 45° or larger than or equal to 45°.

The fifth surface 23A and the sixth surface 23B may be crystal planes that appear due to the anisotropy of quartz crystal in etching when the quartz crystal blank 3 is formed by etching. The crystal planes that appear in this case (in another viewpoint, the inclination angle θ1) may be selected as appropriate by setting the etching conditions. An example of the inclination angle θ1 is approximately 55° (for example, 53° or more and 57° or less). In an example in which the positive-negative direction of the X axis is opposite to that of the illustrated example, the inclination angle θ1 is, for example, approximately 27° (for example, 25° or more and 29° or less).

The first surface 19A and the fifth surface 23A intersect each other and form a corner in side view or in cross-sectional view (as viewed in the Z′ direction). Although not illustrated, this corner may include a curve or a step when viewed extremely microscopically. In this case, the length of a curve or the height of a step is, for example, less than 0.1 μm. A curve or a step may be interposed between the first surface 19A and the fifth surface 23A when viewed not microscopically. The boundary between the first surface 19A and the fifth surface 23A is as described above, and the above description may be applied to the boundary between the second surface 19B and the sixth surface 23B.

The positions of the boundary between the first surface 19A and the fifth surface 23A and the boundary between the second surface 19B and the sixth surface 23B in the direction in which the intermediate portion 17 and the vibration portion 11 are adjacent to each other (the X direction, in the illustrated example) may be the same as or different from each other. It goes without saying that when these positions are judged to be the same, tolerances are taken into account.

The third surface 21A and the fifth surface 23A intersect each other and form a corner in side view or in cross-sectional view (as viewed in the Z′ direction). Although not illustrated, this corner may have a curve or a step when viewed microscopically. For example, a step that includes a flat surface extending from the edge portion 21a of the third surface 21A in the −Y′ direction and approximately orthogonal to the X axis may be formed. The height (the length in the Y′ direction) of this step is, for example, less than 1 μm. The boundary between the third surface 21A and the fifth surface 23A is as described above, and the above description can be applied to the boundary between the fourth surface 21B and the sixth surface 23B.

The positions of the boundary between the third surface 21A and the fifth surface 23A and the boundary between the fourth surface 21B and the sixth surface 23B in the direction in which the fixation portion 13 and the intermediate portion 17 are adjacent to each other (the X direction, in the illustrated example) may be the same as or different from each other. It goes without saying that when these positions are judged to be the same, tolerances are taken into account.

### (1.2. Conductor Pattern)

The material of the conductor patterns 5 may be, for example, a metal. Each conductor pattern 5 may be one metal layer composed of a single material or may be a laminate consisting of a plurality of metal layers composed of different materials. Examples of the materials of metal layers include nickel, chrome, nichrome, titanium, gold, silver, and an alloy including some of these. For example, the entire region (in other words, the total area) of the conductor patterns 5 may be composed of the same material, or part of the region may be composed of a different material.

### (1.2.1. Excitation Electrode)

The pair of excitation electrodes 7 are located on both main surfaces of the vibration portion 11 to apply a voltage to the vibration portion 11 as described above. The pair of excitation electrodes 7 have, for example, the positions, shapes, and sizes with which the excitation electrodes 7 nearly fully overlap each other in transparent plan view. However, the pair of excitation electrodes 7 may include portions that do not overlap each other. The positions, shapes, sizes, and the like of the excitation electrodes 7 in plan view may be determined as appropriate.

For example, each of the excitation electrodes 7 is located in a center region of the vibration portion 11. In another viewpoint, the excitation electrode 7 is located away from the outer edge of the vibration portion 11. The center of the excitation electrode 7 is, for example, approximately aligned with the center of the vibration portion 11 and/or the center of the main surface in the Z′ direction. The center of the excitation electrode 7 may be aligned with or may be on the +X side of or on the −X side of the center of the vibration portion 11 in the X direction. The excitation electrode 7 may occupy, for example, one-third or more of the area of the vibration portion 11.

For example, the excitation electrode 7 may have a shape similar to that of the vibration portion 11 (the example in FIG. 1) or different from that of the vibration portion 11. Examples of the former case include a configuration in which the vibration portion 11 has a rectangular shape, and the excitation electrode 7 has a rectangular shape and includes long sides parallel to the long sides of the vibration portion 11, as in the example of FIG. 1 (at least one of the shapes may be a square). Examples of the latter case include a configuration in which the vibration portion 11 has a rectangular shape, and the excitation electrode 7 is circular (an example of FIG. 11 described later), elliptical, or polygonal (other than quadrangular shapes).

### (1.2.2. Extension Electrode)

Each extension electrode 9 includes a pad portion 9a configured to be joined to a pad 111 of the package 103 and a wiring portion 9b coupling the pad portion 9a to the excitation electrode 7.

The pad portion 9a of each conductor pattern 5 overlies at least the lower surface (the surface on the pad 111 side in FIG. 7. In the following, the same and/or a similar definition applies to the surfaces of other portions.) of the fixation portion 13. Specifically, the pair of pad portions 9a of the pair of the conductor patterns 5 are located side by side on the lower surface of the fixation portion 13.

In the illustrated example, each conductor pattern 5 includes a pad portion 9a also on the upper surface (the surface on the side opposite to the pads 111. In the following description, the same and/or a similar definition applies to the surfaces of other portions.) of the fixation portion 13. In other words, each conductor pattern 5 includes two the pad portions 9a, and hence the pair of conductor patterns 5 include two pairs of pad portions 9a in total. This configuration, for example, enables each of the main surfaces of the quartz crystal element 1 to face downward. Note that unlike the illustrated example, a configuration in which the pair of conductor patterns 5 only includes a pair of pad portions 9a is also possible.

The pair of pad portions 9a on the lower surface (or the upper surface) of the quartz crystal element 1 are located side by side in the Z′ direction. The pair of pad portions 9a on the lower surface (or the upper surface) may have, for example, the positions, shapes, and sizes nearly line-symmetric with respect to the center line CL of the quartz crystal blank 3 parallel to the X axis. The pair of pad portions 9a on the lower surface and the pair of pad portions 9a on the upper surface may include the same configuration.

In each conductor pattern 5, the pad portion 9a on the upper surface and the pad portion 9a on the lower surface of the quartz crystal element 1 are coupled to each other with portions (the symbols of which are omitted) of each conductor pattern 5 located on the side surface facing the X direction and/or on the side surface facing the Z′ direction of the quartz crystal blank 3. With this configuration, the excitation electrode 7 on the upper surface (or the lower surface) is coupled to the pad portion 9a on the lower surface (or the upper surface). Unlike the illustrated example, in a configuration without the pad portions 9a on the upper surface, for example, an excitation electrode 7 on the upper surface and a pad portion 9a on the lower surface may be coupled to each other by a wiring portion 9b extended on the side surface facing the X direction and/or on the side surface facing the Z′ direction of the quartz crystal blank 3.

The specific position, shape, size, and the like of each pad portion 9a may be determined as appropriate. In the illustrated example, the pad portion 9a is rectangular. Unlike the illustrated example, the pad portion 9a may include a recess at a portion opposite to the vibration portion 11 and at the center of the fixation portion 13 in the Z′ direction. In the illustrated example, the pad portion 9a not only overlaps the fixation portion 13 but also extends over the edge portion 21a and overlaps the intermediate portion 17, and it also overlaps the vibration portion 11. On the fixation portion 13, the pad portion 9a reaches the end portion on the side (the +X side) opposite to the vibration portion 11 and also reaches the end portion in the +Z′ direction or the −Z direction. In terms of the pad portion 9a, any one of the length of in the X direction and the length in the Z′ direction may be longer than the other. The length of the pad portion 9a in the Z′ direction may be longer than or equal to one-third of the length of the fixation portion 13 in the Z′ direction (the illustrated example) or may be shorter than one-third of the length of the fixation portion 13 in the Z′ direction.

In each conductor pattern 5, the wiring portion 9b, for example, extends from the excitation electrode 7 to a portion of the pad portion 9a on the surface (the upper surface or the lower surface) on which the excitation electrode 7 is located. In the illustrated example, the pad portion 9a overlaps not only the fixation portion 13 (more specifically, the third surface 21A or the fourth surface 21B) but also the vibration portion 11 (more specifically, the first surface 19A or the second surface 19B), as described above, so that the wiring portion 9b overlaps only the vibration portion 11 and does not overlap the fixation portion 13.

The specific position, shape, size, and the like of the wiring portion 9b may be determined as appropriate. In the illustrated example, the wiring portion 9b has a fixed width and extends parallel to the X direction from an end portion of the edge portion on the fixation portion 13 side of the excitation electrode 7. Unlike the illustrated example, the wiring portion 9b may extend from a corner of the excitation electrode 7, may extend obliquely in the X direction, or may have a varying width. Only for confirmation, the width of the wiring portion 9b (the length in the Z′ direction) is smaller than the width of the pad portion 9a (the length in the Z′ direction).

### (1.3. Recess)

In the following, first, a description will be given of an outline of the recesses 15, and after that, a specific example (one example) of the shape and dimensions of the recess 15 will be described with reference to FIGS. 3 to 5.

In the following description, of the recesses 15 on the third surface 21A side and the recesses 15 on the fourth surface 21B side, the former ones are sometimes taken as an example, for convenience. In this case, unless a contradiction or the like occurs, the description of the recesses 15 on the third surface 21A side can be applied to the recesses 15 on the fourth surface 21B side. In this case, the word “third surface 21A” is interchangeably replaced with the word “fourth surface 21B”, the word “first surface 19A” is interchangeably replaced with the word “second surface 19B”, the word “fifth surface 23A” is interchangeably replaced with the word “sixth surface 23B”, the word “+Y” is interchangeably replaced with the word “−Y”, and the word “+Z′” is interchangeably replaced with the word “−Z”.

### (1.3.1. Outline of Recess)

As described above, each recess 15 has a shape in which the third surface 21A of the fixation portion 13 is recessed, and the edge portion 21a of the third surface 21A on the vibration portion 11 side is cut in in plan view. In the present embodiment, the intermediate portion 17 is located on the vibration portion 11 side of the fixation portion 13, and hence, in the shape of the recess 15, the fifth surface 23A of the intermediate portion 17 is also recessed. The recess 15 may reach the edge portion of the intermediate portion 17 on the vibration portion 11 side in plan view (the illustrated example) or may stop before reaching the edge portion.

The number of recesses 15 is not particularly limited. For example, a plurality of recesses 15 is present in the third surface 21A of the quartz crystal blank 3 in the illustrated example. The third surface 21A includes one or more (two or more, in the illustrated example, more specifically, three) recesses 15 overlapping each extension electrode 9 (more specifically, each pad portion 9a). When the number of recesses 15 is two or more for each extension electrode 9, the number may be, for example, two or more and five or less, or two or more and four or less. Unlike the illustrated example, the third surface 21A may include only one recess 15 for each extension electrode 9 (two recesses 15 in total in the third surface 21A). As can be understood from FIG. 8 described later, the third surface 21A may include a recess 15 only for the extension electrode 9 coupled to the excitation electrode 7 that overlies the first surface 19A connected to the third surface 21A. In other words, the third surface 21A need not include a recess 15 for the extension electrode 9 coupled to the excitation electrode 7 that overlies the second surface 19B.

On the surface of the quartz crystal blank 3 on the +Y′ side or the −Y′ side, the positions of the recesses 15 may be line-symmetric with respect to the center line CL of the quartz crystal blank 3 parallel to the X direction (the illustrated example) but are not limited to being line-symmetric. When they are line-symmetric, the way in which vibration leaked and propagating from the portion of the vibration portion 11 flanked between the pair of excitation electrodes 7 is reflected in the regions where the plurality of recesses 15 are located can be the same between the +Z′ side and the −Z′ side relative to the center line CL. In the Z′ direction, the pitch of the plurality of recesses 15 (for example, the distance between the centers of the recesses 15) or the space between the plurality of recesses 15 (the length in the Z′ direction of the region where the recesses 15 are not located) may be uniform on one side (the +Z′ side or the −Z′ side) of the center line CL (the illustrated example) but is not limited to being uniform. The space between the recesses 15 may be the same as and/or similar to the width of the recess 15 (the length in the Z′ direction, for example, the maximum width) (the illustrated example) or may be smaller than or larger than the width of the recess 15.

The shapes and dimensions of the plurality of recesses 15 may be the same or may be different. In the illustrated example, each of the recesses 15 has basically the same shape and dimensions.

The shape and dimensions of each recess 15 is not particularly limited. For example, the vertical depth (the size in the Y′ direction) of each recess 15 may be uniform in the X direction and/or in the Z′ direction but a configuration in which the vertical depth is not uniform (the illustrated example) is possible. In another viewpoint, the inner surfaces of the recess 15 may include an inclined surface inclined relative to the Y′ direction (the illustrated example) but is not limited to the configuration including an inclined surface. Such an inclined surface may be a crystal plane that appears by etching but not limited to a crystal plane.

In addition, for example, the height (the position in the Y′ direction) of the recess 15, having a shape in which the third surface 21A is recessed, at the end portion on the vibration portion 11 side (the −X side) in plan view may be the same as and/or similar to the height of the first surface 19A (the illustrated example) or may be larger than or smaller than the height of the first surface 19A. In other words, the vertical depth of the aforementioned end portion of the recess 15 from the third surface 21A may be the same as and/or similar to the height h1 from the first surface 19A to the third surface 21A (the illustrated example) or may be smaller than or larger than the height h1. For example, the vertical depth of the aforementioned end portion of the recess 15 from the third surface 21A may be 50% or more and 100% or less of the height h1 from the first surface 19A to the third surface 21A.

The horizontal depth of the recess 15 from the edge portion 21a of the third surface 21A on the vibration portion 11 side in plan view (the length of the recess 15 in the X direction. When it varies depending on the position in the Z′ direction or the Y′ direction, for example, the maximum length) may be the same as and/or similar to the width of the recess 15 (the length in the Z′ direction. When it varies depending on the position in X direction or the Y′ direction, for example, the maximum length) (the illustrated example) or may be larger than or smaller than the width of the recess 15. The vertical depth of the recess 15 (the length of the recess 15 in Y′ direction. When it varies depending on the position in the X direction or the Z′ direction, for example, the maximum length) may be smaller than, the same as and/or similar to, or larger than the horizontal depth of the recess 15 and/or the width of the recess 15.

The overall shape of the recess 15 in plan view (in another viewpoint, the shape of the opening of the recess 15 on the +Y′ side) may be, for example, a rectangular shape (the illustrated example), a triangular shape one side of which is located on the vibration portion 11 side, a semicircular shape the chord of which is located on the vibration portion 11 side, an elliptical shape, or an oval shape (a shape formed by curving the short sides of a rectangle outward). When the overall shape of the recess 15 in plan view is a rectangular shape, for example, the reproducibility in manufacturing the recesses 15 is high. The same and/or a similar configuration can apply to the shape in plan view of the portion of the recess 15 located in the fixation portion 13.

### (1.3.2. Specific Example of Shape and Dimensions of Recess)

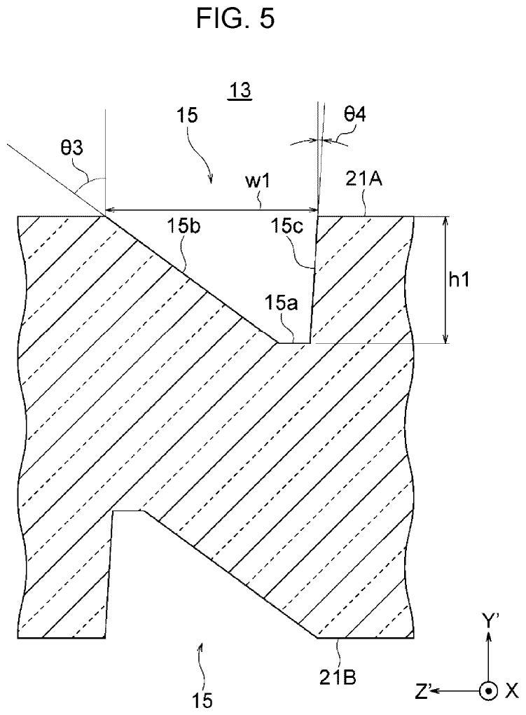

FIG. 3 is an enlarged plan view of region III in FIG. 2. FIG. 4 is a cross-sectional view taken along line IV-IV in FIG. 3. FIG. 5 is a cross-sectional view taken along line V-V in FIG. 3. In FIGS. 3 to 5, illustration of the conductor patterns 5 is omitted, and only the quartz crystal blank 3 is illustrated.

Note that in FIGS. 1 and 2, the shapes of the recesses 15 are illustrated more schematically than in FIGS. 3 to 5. Specifically, the first side surface 15b and a second side surface 15c, which are described later, are depicted so as to be parallel to the Y′ axis, instead of being inclined relative the Y′ axis. However, a configuration in which most of the first side surface 15b and the second side surface 15c are really parallel to the Y′ axis as illustrated in FIGS. 1 and 2 is possible.

Here, the recesses 15 are assumed to be formed by etching in some cases. FIGS. 3 to 5 illustrate an example of the shape of a recess 15 affected by the characteristic effects of the anisotropy of quartz crystal in etching. In the following description, expressions are sometimes made based on the illustrated shape. However, an actual shape may be a little different from the illustrated shape (for example, a shape with relatively largely rounded corners).

The recess 15 includes, for example, the bottom surface 15a nearly orthogonal to the Y′ axis and a plurality of side surfaces rising from the bottom surface 15a in directions on the +Y′ side and surrounding the bottom surface 15a (the first side surface 15b, the second side surface 15c, and the third side surface 15d). The first side surface 15b and the second side surface 15c, in plan view, intersect (for example, are orthogonal to) the edge portion 21a of the fixation portion 13 on the vibration portion 11 side. In other words, the first side surface 15b and the second side surface 15c are located in the direction parallel to the edge portion 21a relative to the bottom surface 15a. The third side surface 15d is located on the side of the bottom surface 15a opposite to the vibration portion 11 in plan view.

Note that although not illustrated, for example, the recess 15 may have a triangular shape one side of which is located on the vibration portion 11 side or a semicircular shape the chord of which is located on the vibration portion 11 side, as mentioned earlier. As in these configurations, a configuration in which the first side surface 15b, the second side surface 15c, and the third side surface 15d cannot be clearly distinguished is possible. In another viewpoint, the presence of three side surfaces is not indispensable to the recess 15.

The bottom surface 15a is, for example, connected to the first surface 19A of the vibration portion 11 and is flush with the first surface 19A. Being flush denotes two surfaces having the same height and parallel to each other. As can be understood from the description of the outline of the recess 15, the bottom surface 15a, unlike the illustrated example, may have a height different from that of the first surface 19A, may be inclined relative to the first surface 19A, or may include a configuration in which the bottom surface 15a does not reach the first surface 19A in plan view.

At least one selected from the group consisting of the first side surface 15b, the second side surface 15c, and the third side surface 15d (all of the side surfaces, in the illustrated example) is an inclined surface (includes an inclined surface) inclined relative to the thickness direction (the Y′ direction) of the quartz crystal blank 3. More specifically, each inclined surface is inclined, for example, in such an orientation that the size of the recess 15 (the width or the horizontal depth) increases toward the upper side of the recess 15 (the +Y′ side or the third surface 21A side in this case). The inclination angle of each inclined surface relative to the Y′ direction (02 in FIGS. 4, 03 and 04 in FIG. 5) may be determined as appropriate. For example, each inclination angle may be 1° or more, 10° or more, 20° or more, or 50° or more, or may be 70° or less, 60° or less, 40° or less, or 30° or less, and any upper limit and lower limit mentioned above may be combined so as not to cause a contradiction.

Note that unlike the illustrated example, each side surface, instead of consisting of one plane, may include a plurality of planes at different positions in the Y′ direction or may include one or more curved surfaces concave and/or convex in cross-sectional view. In another viewpoint, each side surface, in a cross section parallel to the Y′ direction, may include two or more straight lines or one or more curved lines, instead of consisting of one straight line. When the inclination angle of each side surface is mentioned without specific notation, an explanation of this inclination angle may be interpreted as an explanation of a typical value of the inclination angles of each side surface, unless a contradiction or the like occurs. The typical value can be, for example, the inclination angle of one plane that occupies 50% or more or 80% or more of the area of each side surface, or it can be the value obtained by averaging the inclination angle of each position over the entire area of each side surface. In addition or alternatively, the typical value can be the inclination angle of a straight line that occupies 50% or more or 80% or more of the height of each side surface in the Y′ direction in a cross section parallel to the Y′ direction at a certain position on each side surface, or it can be the value obtained by averaging the inclination angle of each position over the entire length of each side surface.

At least one selected from the group consisting of the first side surface 15b, the second side surface 15c, and the third side surface 15d (all of the side surfaces, in the illustrated example) is, for example, a crystal plane (includes a crystal plane) that appears due to the anisotropy of quartz crystal in etching. The inclined surfaces mentioned above may be formed by using crystal planes. The crystal planes that appear in this case (in another viewpoint, the inclination angles from θ2 to θ5) may be selected as appropriate by setting the etching conditions.

The following are examples of inclination angles when each side surface is a crystal plane. The inclination angle θ2 of the third side surface 15d relative to the Y′ axis may be the same as or different from the inclination angle θ1 (mentioned earlier) of the fifth surface 23A of the intermediate portion 17. They are the same in the example of FIG. 4. For example, the inclination angle θ2 may be approximately 55° (for example, 53° or more and 57° or less). When the positive-negative direction of the X axis is opposite to that in the illustrated example, the inclination angle θ2 may be approximately 27° (for example, 25° or more and 29° or less). The inclination angle θ3, relative to the Y′ axis, of the side surface facing the −Z′ side (the first side surface 15b, in the illustrated example) out of the first side surface 15b and the second side surface 15c of the recess 15 on the +Y′ side may be approximately 54° (for example, 52° or more and 56° or less). The inclination angle θ4, relative to the Y′ axis, of the side surface facing the +Z′ side (the second side surface 15c, in the illustrated example) out of the first side surface 15b and the second side surface 15c of the recess 15 on the +Y′ side may be approximately 3° (for example, 1° or more and 5° or less).

Unlike the illustrated example, only part of each side surface may consist of a crystal plane. Each side surface may include two or more different crystal planes at different positions in the Y′ direction (inclined surfaces having different inclination angles). One inclination angle of the one or more crystal planes of each side surface may be within the range mentioned above. The crystal plane having an inclination angle in the range mentioned above may occupy a large part of each side surface but is not limited to this configuration. A crystal plane occupying a large part of each side surface may occupy 50% or more, 80% or more, or 100% of the area of each side surface (without minute round shapes at corners taken into account). In addition or alternatively, a crystal plane occupying a large part of each side surface may occupy 50% or more, 80% or more, or 100% of the height of each side surface in the Y′ direction (without minute round shapes at corners taken into account) in a cross section parallel to the thickness direction (the Y′ direction) of the quartz crystal blank 3.

The third side surface 15d is inclined at an inclination angle of θ2. Hence, when h1 (FIG. 4) is defined as the height from the first surface 19A of the vibration portion 11 to the third surface 21A of the fixation portion 13, the third side surface 15d in plan view extends from the edge portion connected to the third surface 21A (the edge portion of the recess 15 on the +X side) toward the vibration portion 11 side by a length of h1×tan θ2 (the length in plan view). In plan view, d1 is defined as the horizontal depth of the recess 15 from the edge portion 21a of the fixation portion 13 at the height of the third surface 21A (FIGS. 3 and 4). When the horizontal depth d1 is larger than h1×tan θ2, the bottom surface 15a includes a region protruding from the edge portion 21a into the fixation portion 13 by the difference d2 (FIGS. 3 and 4) (the illustrated example). This region, for example, reduces the effects of the vibration reflected on the first side surface 15b and the third side surface 15d. Although this region may have any shape, the illustrated one is a square. When this region is a square (the illustrated example), and θ2 is larger than 0°, d2 is smaller than d1. The specific length d2 is not particularly limited. For example, d2 may be ¼×d1 or more and ¾×d1 or less, or ⅓×d1 or more and ⅔×d1 or less. The width w2 of this region is usually smaller than the width w1 of the recess 15 (the width at the height of the third surface 21A). The specific length w2 is not particularly limited. For example, w2 may be ¼×w1 or more and ¾×w1 or less, or ⅓×w1 or more and ⅔×w1 or less. Unlike the illustrated example, the end portion of the third side surface 15d on the vibration portion 11 side may be located at the edge portion 21a or may be located on the vibration portion 11 side of the edge portion 21a.

The first side surface 15b is inclined at an inclination angle of θ3. Hence, the first side surface 15b in plan view extends from the edge portion connected to the third surface 21A (the edge portion of the recess 15 on the +Z′ side) into the recess 15 by a length of h1×tan θ3 (the length in plan view). Also, the second side surface 15c is inclined at an inclination angle of θ4 and extends in plan view from the edge portion connected to the third surface 21A (the edge portion of the recess 15 on the −Z′ side) into the recess 15 by a length of h1×tan θ4 (the length in plan view). In plan view, w1 is defined as the width of the recess 15 at the height of the third surface 21A of the fixation portion 13 (FIGS. 3 and 5). When the width w1 is larger than the sum of h1×tan θ3 and h1×tan θ4, the first side surface 15b and the second side surface 15c do not directly intersect each other, and part of the bottom surface 15a is formed therebetween (the illustrated example). An example of the width w2 of this part was mentioned above. Unlike the illustrated example, the first side surface 15b and the second side surface 15c may directly intersect each other.

As can be understood from the above description, in the illustrated example, the width w1 and the horizontal depth d1 are set to be relatively large. For example, the width w1 and/or the horizontal depth d1 are larger than the thickness t1 of the vibration portion 11 (FIG. 4), the height h1 from the first surface 19A to the third surface 21A, and the length s1 of the fifth surface 23A in plan view (FIGS. 3 and 4).

Specific values for these are not particularly limited. The following is an example of a relatively thin quartz crystal blank 3. The thickness t1 may be set to 16 μm or less. The height h1 may be set to 16 μm or less or 12 μm or less. The length s1 is, for example, h1×tan θ1 and may be set to, for example, 17 μm or less or 6 μm or less (which is, for example, smaller than the horizontal depth d1). The width w1 and/or the horizontal depth d1 may be set to 17 μm or more or 19 μm or more.

(1.4. Overlap between Extension Electrode and Recess)

In terms of the extension electrode 9, appropriate portions of the extension electrode 9 may pass appropriate portions of the inner surfaces of the recesses 15 in the course from the vibration portion 11 (the first surface 19A) to the fixation portion 13 (the third surface 21A). In the illustrated example, the pad portion 9a of the extension electrode 9 overlaps the entire inner surfaces of (at least one of) the recesses 15. Specifically, the pad portion 9a overlaps the entire portion of each of the bottom surface 15a, the first side surface 15b, the second side surface 15c, and the third side surface 15d. In other words, the pad portion 9a extends from the bottom surface 15a flush with the first surface 19A via the lower-end edge portions of the three side surfaces to the three side surfaces, and further extends via the upper-end edge portions of the three side surfaces to the third surface 21A.

Unlike the illustrated example, the wiring portion 9b may overlap a recess 15 (refer to FIG. 8 described later). The extension electrode 9 may overlap only part of the recess 15. For example, a possible configuration may be such that the extension electrode 9 overlaps all or part of the bottom surface 15a and overlaps all or part of one side surface of the three side surfaces (15c, 15b, and 15d) but does not overlap at least part or all of at least one of the remaining two side surfaces.

### (1.5. Method of Manufacturing Quartz Crystal Element)

The quartz crystal element 1 may be fabricated by using various publicly-known manufacturing methods. Although not illustrated, the following describes an example of a method.

First, a wafer composed of quartz crystal is prepared. A plurality of quartz crystal blanks 3 is fabricated from the wafer by multi-chip processing. Such a wafer is, for example, cut out at a cut angle of an AT-cut plate mentioned earlier and is processed so as to have a thickness the same as and/or similar to that of the fixation portion 13.

Then, etching masks are formed on both main surfaces of the wafer. These etching masks overlie, for example, the regions assigned to quartz crystal blanks 3 (vibration portions 11, intermediate portions 17, and fixation portions 13) and the region assigned to a frame shape portion (margin) around the plurality of quartz crystal blanks 3. Then, the wafer is etched from both main surface sides through the etching masks. The etching is, for example, wet etching in which the wafer is immersed in a chemical solution. With this process, the surroundings of the regions assigned to quartz crystal blanks 3 are etched, thereby forming the outer shapes of the quartz crystal blanks 3.

Then, new etching masks are formed on both main surfaces of the wafer. The new etching masks overlie the regions assigned to third surfaces 21A and fourth surfaces 21B (and does not overlie the regions assigned to vibration portions 11, intermediate portions 17, and recesses 15). Note that these new etching masks may be formed by removing parts of the previous etching masks.

Then, the wafer is etched from the both main surface sides through the new etching masks. This process makes the regions assigned to vibration portions 11 thinner than the regions assigned to fixation portions 13. Because of the anisotropy of quartz crystal in etching, crystal planes appear between the vibration portions 11 and the fixation portions 13, which forms intermediate portions 17, the thickness of which increases toward the fixation portions 13, between the vibration portions 11 and the fixation portions 13. The etching also forms recesses 15. Because of the anisotropy of quartz crystal in etching, the side surfaces of the recesses 15 are inclined surfaces inclined in such an orientation that the size of the recess 15 increases toward the upper portion of the recess 15.

After that, the etching masks are removed, and conductor patterns 5 are formed. The conductor patterns 5 may be formed, for example, by forming metal films through the masks formed on the surfaces of the quartz crystal blanks 3. Alternatively, the conductor patterns 5 may be formed by forming metal films on all or most of the surfaces of the quartz crystal blanks 3 and then performing etching through the masks. The film formation may be performed by an appropriate method such as sputtering.

After forming the conductor patterns 5, the quartz crystal blanks 3 are separated (divided into pieces) from the frame shape portion by snapping off or cutting off the connecting portions between the quartz crystal blanks 3 and the frame shape portion of the wafer. Note that while being divided into pieces and/or after divided into pieces, the fixation portions 13 may be used to hold the quartz crystal elements 1. For example, the quartz crystal element 1 may be held on a jig by sucking and holding the fixation portion 13.

### (1.6. Summary of Quartz Crystal Element)

As described above, in the present embodiment, the quartz crystal element 1 includes a piezoelectric blank (the quartz crystal blank 3), a first excitation electrode (for example, the excitation electrode 7 of the first conductor pattern 5A), and a first extension electrode (for example, the extension electrode 9 of the first conductor pattern 5A). The quartz crystal blank 3 includes the vibration portion 11 and the fixation portion 13 including different regions in plan view. The vibration portion 11 includes the first surface 19A facing a first side (the +Y′ side) and the second surface 19B facing a second side (the −Y′ side) opposite to the first side. The fixation portion 13 includes the third surface 21A facing the +Y′ side and the fourth surface 21B facing the −Y′ side. The third surface 21A is higher than the first surface 19A in the +Y′ direction. The excitation electrode 7 overlies the first surface 19A. The extension electrode 9 is extended from the excitation electrode 7 and overlies the third surface 21A. The quartz crystal blank 3 includes a first recess (a recess 15 on the +Y′ side) recessed from the third surface 21A toward the −Y′ side. The recess 15 has a shape in plan view in which a first edge portion (the edge portion 21a) of the third surface 21A on the first surface 19A side is cut in. The extension electrode 9 includes a portion extending from the first surface 19A via the recess 15 to the third surface 21A.

Thus, for example, the recess 15 improves the reliability of the electrical continuity of the extension electrode 9. A specific description is as follows.

For example, when the conductor pattern 5 is formed by sputtering, some regions of the first surface 19A of the vibration portion 11 (and the fifth surface 23A of the intermediate portion 17) are, in some cases, hidden behind the fixation portion 13 from metal particles flying in directions including a component of the −X direction. The probability of the extension electrode 9 being thin in the hidden regions is high. Hence, the cross section contributing to the electrical continuity from the vibration portion 11 to the fixation portion 13 reduces. When such a reduction in the cross section occurs, for example, the crystal impedance of the quartz crystal element 1 increases, and electrical characteristics of the quartz crystal element 1 deteriorate.

However, when the quartz crystal blank 3 includes the recess 15, parts of the hidden regions are shifted to the fixation portion 13 side (the +X side). This makes it easy, for example, to attach metal particles to the regions exposed by the shifting. Thus, a sufficient cross section can be ensured for contributing to the electrical continuity from the vibration portion 11 to the fixation portion 13, for example, by the presence of the portions of the extension electrode 9 extending from the exposed regions in directions including a Z′-direction component to the fifth surface 23A and/or the third surface 21A.

In addition, for example, the edge portion 21a of the third surface 21A is apt to include an edge and/or a step. In this case, the extension electrode 9 is apt to be thin, and/or the stress received from the quartz crystal blank 3 is apt to be high. This increases the probability that the cross section contributing to the electrical continuity may be reduced at the edge portion 21a.

However, the edge portion 21a cut in by the recess 15, for example, increases the length of the edge portion of the third surface 21A including the length of the portion recessed by the presence of the recess 15, which in turn makes it possible to increase the length of the portion of the conductor pattern 5 over both sides of the edge portion of the third surface 21A (here, including the edge portion of the recess 15). In addition, for example, even when a step is formed at the edge portion 21a (in another viewpoint, the edge portion orthogonal to the X axis in plan view), a step is not formed in some cases at the edge portions of the recess 15 intersecting the edge portion 21a (the upper-end edge portions of the first side surface 15b and/or the second side surface 15c). In this case, the conductor pattern 5 can reach the third surface 21A from the bottom surface 15a of the recess 15 without passing the step. For these reasons, a sufficient cross section contributing to the electrical continuity is likely to be ensured.

An example of an effect of improving the reliability of the electrical continuity has been described as above, and the recess 15 provides other effects. Examples are described below.

The formation of the recesses 15 makes it possible to reduce the stiffness of parts of the vibration portion 11 while ensuring a sufficient strength of the fixation portion 13 as a whole. Hence, for example, when the bumps 105 (FIG. 7) for mounting the quartz crystal element 1 exert strain on the fixation portion 13, a portion of the fixation portion 13 on the vibration portion 11 side absorbs the strain, reducing the probability of the strain affecting the vibration portion 11. This reduces the probability of deterioration in characteristics. Such a strain mentioned above occurs, for example, due to solidification and contraction of the bumps 105 and/or a warp of a base plate 107a (FIG. 7) described later on which the quartz crystal element 1 is mounted.

In addition, for example, when the entire edge portion of the fixation portion 13 on the vibration portion 11 side is straight, the waves that travel from the vibration portion 11 to various positions of the edge portion of the fixation portion 13 are reflected in the same direction in the same phase, which increases the probability that the reflected waves act as noises. However, the presence of the recesses 15 forms curved portions or bent portions in the whole edge portion (here, including the edge portions of the recesses 15) of the fixation portion 13 on the vibration portion 11 side, making it likely for the directions and/or phases of reflected waves to be dispersed. As a result, noises are reduced.

In the recesses 15, the first side surfaces 15b intersecting the edge portion 21a in plan view may include a crystal plane.

In this case, for example, the first side surfaces 15b are formed to have the same orientation regardless of variations in etching conditions. This makes it easy, in a plurality of quartz crystal elements 1, to make the shapes of the recesses 15 uniform and reduce variations in characteristics. The crystal planes are apt to appear as inclined surfaces inclined relative to the vertical-depth direction of the recesses 15 (the Y′ direction). This provides the following effects.

When the size of the recess 15 on the +Y′ side in the direction parallel to the edge portion 21a is referred to as the width of the recess 15, the first side surface 15b may include an inclined surface inclined in such an orientation that the width of the recess 15 increases toward the +Y′ side and extending from the bottom portion of the recess 15 to the third surface 21A. The extension electrode 9 may include a portion extending from the bottom portion of the recess 15 via the inclined surface mentioned above to the third surface 21A.

In this case, a film of the extension electrode 9 is more likely to be formed on the first side surface 15b than, for example, in the configuration in which the first side surface 15b is orthogonal to the third surface 21A (this configuration may be included in the technology according to the present disclosure), which in turn increases the effect of improving the reliability of the electrical continuity mentioned above. In an example of sputtering, the reason is that metal particles flying in the vertical-depth direction of the recesses 15 (Y′ direction) are more likely to attach to a side surface inclined relative to the vertical-depth direction than to a side surface parallel to the vertical-depth direction. In addition, for example, the probability of occurrence of a stress concentration is lower, and ensuring a sufficient strength of the fixation portion 13 is easier than in a configuration with a first side surface 15b orthogonal to the third surface 21A. Note that the first side surface 15b may directly intersect the second side surface 15c without the bottom surface 15a interposed therebetween as described above, and the bottom portion mentioned here is not limited to the bottom surface 15a.

When the size of the recess 15 in the direction parallel to the edge portion 21a (the Z′ direction) is referred to as the width of the recess 15, the width w1 of the recess 15 at the height of the third surface 21A (in another viewpoint, the edge portion 21a) may be larger than the thickness t1 of the vibration portion 11.

In this case, the width w1 can be said to be relatively large. In this case, for example, the various effects mentioned above are improved. For example, this makes it easy to ensure, in the Z′ direction, a sufficient area of the portion shifted to the fixation portion 13 side out of the region hidden by the fixation portion 13. This makes it easy, for example, to ensure a sufficient cross section to contribute to the electrical continuity. In addition, for example, this improves the effect of reducing the strain in the vibration portion 11. In addition, this makes it more likely that a crystal plane appears on the first side surface 15b and that the bottom surface 15a protrudes toward the fixation portion 13 side (the first side surface 15b and the second side surface 15c are less likely to directly intersect each other). The effect by the bottom surface 15a protruding toward the fixation portion 13 side will be described later.

Note that in an AT-cut quartz crystal element 1, the thickness t1 is a parameter to define the frequency. Hence, the size of the width w1 defined in comparison to the thickness t1 is highly likely to provide the same and/or similar effects in AT-cut quartz crystal elements 1 in various sizes. The same and/or a similar principle applies to the horizontal depth d1.

The horizontal depth d1 of the recess 15 from the edge portion 21a in plan view at the height of the third surface 21A (in another viewpoint, the edge portion 21a) may be larger than the thickness t1 of the vibration portion 11.

In this case, the horizontal depth d1 can be said to be relatively large. In this case, for example, the various effects mentioned above are improved. For example, the length of the shift of the region to the fixation portion 13 side out of the region hidden by the fixation portion 13 can be long, and the length from the region not hidden in the first place to the shifted region can be long. This makes it easy, for example, to ensure a sufficient cross section to contribute to the electrical continuity. In addition, for example, this makes it more likely that a crystal plane appears on the third side surface 15d and that the bottom surface 15a protrudes toward the fixation portion 13 side (the third side surface 15d is less likely to protrude beyond the edge portion 21a toward the vibration portion 11 side). The effect by the bottom surface 15a protruding toward the fixation portion 13 side will be described later.

When the size of the recess 15 in the direction parallel to the edge portion 21a (the Z′ direction) is referred to as the width of the recess 15, the width w1 of the recess 15 at the height of the third surface 21A (in another viewpoint, the edge portion 21a) may be larger than the height h1 from the first surface 19A to the third surface 21A (the edge portion 21a).

In this case, the width w1 can be said to be relatively large. The effects when the width w1 is relatively large are as described above. When the height h1 is large, for example, the probability that the inside of the recess 15 is hidden is high. However, when the width w1 is larger than the height h1, it reduces the probability of the presence of a portion hidden from the view in directions including a Z′-direction component. Thus, for example, this makes it easy to form a metal film inside the recess 15 and increases the effect of improving the reliability of the electrical continuity.

The horizontal depth d1 of the recess 15 from the edge portion 21a in plan view at the height of the third surface 21A (in another viewpoint, the edge portion 21a) may be larger than the height h1 from the first surface 19A to the third surface 21A (the edge portion 21a).

In this case, the horizontal depth d1 can be said to be relatively large. The effects when the horizontal depth d1 is relatively large are as described above. When the height h1 is large, for example, the probability that the inside of the recess 15 is hidden is high. However, when the horizontal depth d1 is larger than the height h1, it reduces the probability of the presence of a portion hidden from the view in directions including an X-direction component. Thus, for example, this makes it easy to form a metal film inside the recess 15 and increases the effect of improving the reliability of the electrical continuity.

The inner surfaces of the recess 15 may include the bottom surface 15a and an end surface (the third side surface 15d). The bottom surface 15a may be connected to the first surface 19A and be flush with the first surface 19A. The third side surface 15d may be located on the side (the +X side) of the bottom surface 15a opposite to the first surface 19A in plan view and may rise from the bottom surface 15a to the third surface 21A (the edge portion 21a) so as to be inclined in such an orientation that the further away from the bottom surface 15a in plan view, the closer to the height of the third surface 21A (in another viewpoint, the edge portion 21a). The bottom surface 15a may protrude beyond the edge portion 21a into the third surface 21A side in plan view.

In this case, for example, the extension electrode 9 can include a flush portion from the first surface 19A to the bottom surface 15a and also include a portion extending from the bottom surface 15a via the first side surface 15b or the second side surface 15c to the third surface 21A. In other words, the extension electrode 9 can include portions extending from the first surface 19A to the third surface 21A without passing the edge portion 21a and an edge portion having the same orientation as the edge portion 21a (the boundary between the third side surface 15d and the third surface 21A). Thus, for example, even if the extension electrode 9 is thin at the edge portion 21a and the edge portion having similar conditions as the edge portion 21a, reliability of the electrical continuity can be ensured.

The quartz crystal blank 3 may include the fifth surface 23A connecting the first surface 19A to the third surface 21A (in another viewpoint, the edge portion 21a) and inclined such that the further toward the third surface 21A (the edge portion 21a) side, the further toward the first side (the +Y′ side). When the size of the recess 15 in the direction parallel to the edge portion 21a (the Z′ direction) is referred to as the width of the recess 15, the width w1 of the recess 15 at the height of the third surface 21A (the edge portion 21a) may be larger than the length s1 (the length in the X direction) of the fifth surface 23A in plan view from the first surface 19A to the third surface 21A (the edge portion 21a).

In this case, the width w1 can be said to be relatively large. The effects when the width w1 is relatively large are as described above. On the assumption that the total length (in the X direction) of the quartz crystal blank 3 and the length in the X direction of the fixation portion 13 are fixed, if the length s1 is long, the area of the vibration portion 11 is reduced by the intermediate portion 17. In this case, for example, the degree of restraining the vibration of the vibration portion 11 by the intermediate portion 17 and the fixation portion 13 increases, which can degrade the characteristics in some cases. However, if the width w1 of the recess 15 is large, it substantially reduces the volume of the intermediate portion 17 and reduces the probability of occurrence of such a problem.

The horizontal depth d1 of the recess 15 in plan view from the edge portion 21a at the height of the third surface 21A (in another viewpoint, the edge portion 21a) may be larger than the length s1 of the fifth surface 23A in plan view from the first surface 19A to the third surface 21A (the edge portion 21a). In this case, the horizontal depth d1 can be said to be relatively large. The effects when the horizontal depth d1 is relatively large are as described above. When the length s1 is long, the third side surface 15d having a length the same as and/or similar to the length s1 is also long. This in turn makes it difficult to extend the bottom surface 15a toward the third surface 21A side (the +X side). However, if the horizontal depth d1 is larger than the length s1, it reduces the probability of occurrence of such a problem.

The entire part of the recess 15 may overlap the extension electrode 9 in plan view.

In this case, for example, the reliability of the electrical continuity is further improved. For example, even if part of the inner surfaces of the recess 15 is hidden from the view of metal particles flying in specified directions, films are formed on other portions of the inner surfaces of the recess 15, which ensures a sufficient cross section for the electrical continuity. In addition, for example, even if a step is present at the boundary between the third surface 21A and one of the side surfaces of the recess 15, making it more likely for the extension electrode 9 to be thin, the boundaries between the third surface 21A and the other side surfaces are less likely to have such a problem.

The quartz crystal element 1 may include a second excitation electrode (the excitation electrode 7 of the second conductor pattern 5B) overlying the second surface 19B and a second extension electrode (the extension electrode 9 of the second conductor pattern 5B) extended from the second excitation electrode and overlying the fourth surface 21B. The fourth surface 21B may be higher than the second surface 19B in the −Y′ direction. The quartz crystal blank 3 may include second recesses (the recesses 15 on the −Y′ side) recessed from the fourth surface 21B toward the +Y′ side. The second recesses have a shape in plan view that the edge portion 21a of the fourth surface 21B on the second surface 19B side is cut in. The second extension electrode may include a portion extending from the second surface 19B via the second recesses to the fourth surface 21B.

Specifically, the fixation portion 13 is higher than the vibration portion 11 not only on one side in the thickness direction but on both sides in the thickness direction and includes the recesses 15 on both sides. In this case, for example, the various effects of the recess 15 described above can be obtained on both sides of the quartz crystal blank 3. In addition, for example, the distribution of vibration in the vibration portion 11 can be the same and/or similar between both sides, and the probability of occurrence of unintended unusual vibration can be reduced.

The vibration portion 11 may be rectangular in plan view. In plan view, the edge portion 21a of the third surface 21A may extend along one side (one side on the +X side in the present embodiment) of the four sides of the vibration portion 11. When an imaginary line (the center line CL) orthogonal to the one side mentioned above of the vibration portion 11 in plan view is assumed to be drawn, the plurality of recesses 15 may be located line-symmetrically with respect to the center line CL.

In this case, for example, the plurality of recesses 15 improves the various effects mentioned above (for example, the effect of improving the reliability of the electrical continuity). In addition, for example, the distribution of strain generated in the vibration portion 11 can be symmetric with respect to the center line CL. The reason is, for example, that this configuration makes vibration leaked from the vibration portion 11 and reflected on the fixation portion 13 symmetric and/or makes the strain exerted by the two bumps 105 on the vibration portion 11 via the fixation portion 13 symmetric. The improvement in the symmetry of the strain distribution, for example, reduces the probability of occurrence of unintended unusual vibration and improves electrical characteristics of the quartz crystal element 1.

The vertical depth of the recess 15 from the third surface 21A at the end portion of the recess 15 on the vibration portion 11 side in plan view may be 50% or more and 100% or less (100%, in the illustrated example) of the height h1 from the first surface 19A to the third surface 21A.

If the vertical depth of the recess 15 is 50% or more of the height h1, for example, it increases the probability of providing the effect of shifting the hidden region mentioned above toward the fixation portion 13 side. If the vertical depth of the recess 15 is 100% or less of the height h1, for example, it makes it easy to maintain the strength of the fixation portion 13.

In the embodiment described above, the quartz crystal element 1 is an example of a piezoelectric vibration element. The quartz crystal blank 3 is an example of a piezoelectric blank. The +Y′ side is an example of the first side. The −Y′ side is an example of the second side. The excitation electrode 7 of the first conductor pattern 5A is an example of the first excitation electrode. The extension electrode 9 of the first conductor pattern 5A is an example of the first extension electrode. The recesses 15 on the +Y′ side are an example of the first recess. The edge portion 21a on the +Y′ side is an example of the first edge portion. The first side surface 15b is an example of a side surface. The third side surface 15d is an example of an end surface. The excitation electrode 7 of the second conductor pattern 5B is an example of the second excitation electrode. The extension electrode 9 of the second conductor pattern 5B is an example of the second extension electrode. The recesses 15 on the −Y′ side are an example of the second recess. The edge portion 21a on the −Y′ side is an example of the second edge portion.

### 2. Application Example of Quartz Crystal Element 1

FIG. 6 is a perspective view of a quartz crystal device 101 which is an application example of the quartz crystal element 1. FIG. 7 is a cross-sectional view taken along line VII-VII in FIG. 6. Note that although the up-down direction or the horizontal direction of the quartz crystal device 101 can be any direction, in the following description, the upward direction on the drawing plane in FIGS. 6 and 7 is defined as the upward direction, for convenience, and terms such as “upper surface” are used in some cases.

The quartz crystal device 101 is an electronic component having, for example, approximately a rectangular parallelepiped shape as a whole. The dimensions of the quartz crystal device may be determined as appropriate. As an example, the length of the long side or the short side is 0.6 mm or more and 2.0 mm or less, and the thickness in the up-down direction is 0.2 mm or more and 1.5 mm or less. The quartz crystal device 101 is surface-mounted, for example, with its lower surface facing the upper surface of a mount base (not illustrated) (for example, a circuit substrate).

The quartz crystal device 101 is, for example, a vibrator that contributes to generating an oscillation signal the signal strength (for example, voltage and/or current) of which oscillates at a constant frequency. The quartz crystal device 101 includes, for example, a quartz crystal element 1 that generates vibration used for generating an oscillation signal and a package 103 that houses the quartz crystal element 1.

The package 103 includes, for example, a base 107 that supports the quartz crystal element 1 and a lid 109 that is joined to the base 107 and seals the base 107 with the quartz crystal element 1 inside. The quartz crystal element 1 is joined to the base 107, for example, with conductive bumps 105 and is supported by the bumps 105. The internal space of the package 103 is, for example, under vacuum or is sealed with an appropriate gas (for example, nitrogen) filled inside.

The base 107 has, for example, a shape including a recess for housing the quartz crystal element 1. In another viewpoint, the base 107 includes a flat plate-shaped base plate 107a and a frame 107b extending along the edge portions of the upper surface of the base plate 107a. The base 107 consisting of the base plate 107a and the frame 107b is composed of an insulation material such as a ceramic material. The lid 109 is composed of, for example, a metal and is joined to the upper surface of the frame 107b by seam welding or the like.

The package 103 includes conductors that electrically couple the quartz crystal element 1 to a mount base (not illustrated) on which the quartz crystal device 101 is mounted. For example, the package 103 includes pads 111 for mounting the quartz crystal element 1, external terminals 113 for mounting the quartz crystal device 101 onto the mount base, and wire conductors (not illustrated) that couple the pads 111 and the external terminals 113.

The pads 111 are composed of a conductive layer located on the upper surface of the base plate 107a. The external terminals 113 are composed of a conductive layer located on the lower surface of the base plate 107a. The wire conductors (not illustrated) include through conductors extending through the base plate 107a in the upper-lower direction. The material of these conductors is, for example, a metal.

The quartz crystal element 1 is joined to the pads 111 with the bumps 105. With this configuration, the quartz crystal element 1 is supported on the base 107 and also electrically coupled to the package 103. More specifically, for example, the quartz crystal element 1 is joined at its one end side to the pads 111 and thus supported in a manner of a cantilever. The bumps 105 are, for example, composed of a conductive adhesive. The conductive adhesive is composed of a thermosetting resin containing metal fillers mixed therein.

The external terminals 113 are, for example, joined to pads of the mount base (not illustrated) with a solder. With this configuration, the quartz crystal device 101 is supported by and electrically coupled to the mount base.

The quartz crystal element 1 may be used in various configurations other than the application example mentioned above.

For example, the quartz crystal device (the piezoelectric device) including the quartz crystal element 1 may be an oscillator including, in addition to the quartz crystal element 1, an integrated circuit element (IC) configured to generate an oscillation signal by applying a voltage to the quartz crystal element 1. For example, a vibrator may include, in addition to the quartz crystal element 1, other electronic elements such as a thermistor. A piezoelectric device may be an oven controlled one.

In a piezoelectric device, the structure of a package housing the quartz crystal element 1 may include an appropriate configuration. For example, the package may include an H cross section including recesses in the upper and lower faces. The package may include a base in a base-plate shape (a base not including a recess) and a lid in a cap shape configured to be put on the base.

### 3. Other Examples

The following describes various examples with reference to FIGS. 8 to 10. In the following description, basically only differences from the embodiment will be described. Items not referred to may be considered to be the same as and/or similar to those in the embodiment or may be inferred from the embodiment.

### (3.1. Other Examples of Extension Electrode and Recess)

FIG. 8 is a plan view of a quartz crystal element 201 according to another example from the +Y′ side.

As with the extension electrode 9 of the embodiment, an extension electrode 209 of the quartz crystal element 201 includes a pad portion 209a and a wiring portion 209b. However, the wiring portion 209b is longer than the wiring portion 9b of the embodiment and overlies not only the vibration portion 11 but also an intermediate portion 17 and a fixation portion 13. On the fixation portion 13, the correspondence relationship between the length of the wiring portion 209b in the X direction and the length of the pad portion 209a in the X direction is not particularly limited. For example, the former may be longer than the latter (the illustrated example) or may be the same as and/or similar to or shorter than the latter.

The plan view of the quartz crystal element 201 from the −Y′ side may be, for example, the same as and/or similar to or different from the one in FIG. 8. In other words, the former suggests that the quartz crystal element 201 may be 180-degree rotationally symmetric with respect to the center line (not illustrated) parallel to the X direction. Examples of the latter include a configuration in which the pad portion 209a (not illustrated) on the −Y′ side is larger in the X direction than the pad portion 209a on the +Y′ side illustrated in FIG. 8. In this case, the quartz crystal element 201 is mounted in the package 103, for example, such that the pad portion 209a on the −Y′ side faces a pad 111 of the package 103. In this case, the pad portion 209a on the +Y′ side is not necessarily joined to a bump 105 (does not necessarily contribute to mounting). However, in this example, even in the case of the above configuration, the portion on the +Y′ side wider than the wiring portion 209b is referred to as a pad portion 209a, for convenience.

The quartz crystal element 201 includes a recess 215 in the fixation portion 13 as in the embodiment. The extension electrode 209 overlaps at least part (all, in the illustrated example) of the recess 215. In this example, at least part (all, in the illustrated example) of the recess 215 overlaps the wiring portion 209b. Note that as described above, the pad portion 209a on the −Y′ side may be larger in the X direction than the pad portion 209a on the +Y′ side. In this case, unlike the +Y′ side, the pad portion 209a on the −Y′ side may overlap part or all of the recess 215.

In the illustrated example, the third surface 21A includes only one recess 215 for one conductor pattern 205 (a first conductor pattern 205A in FIG. 8). However, in a configuration in which the wiring portion 209b overlaps the recess 215, the third surface 21A may include one or more recesses 215 for each of the first conductor pattern 205A and a second conductor pattern 205B as in the embodiment. Alternatively, the third surface 21A may include two or more recesses 215 only for one conductor pattern 205. In the illustrated example, the recess 215 has an elongated shape in plan view. However, the recess 215 overlapping the wiring portion 209b may have any shape and dimensions, as with the recess 15 in the embodiment. Note that as described above, description of the recess 215 in the third surface 21A may be applied to that of the recess 215 in the fourth surface 21B.

As described above, the first extension electrode (the extension electrode 209 of the first conductor pattern 205A) may include the wiring portion 209b and the pad portion 209a. The wiring portion 209b may extend from the first excitation electrode (the excitation electrode 7 of the first conductor pattern 205A). The pad portion 209a may be connected to the wiring portion 209b and may be wider than the wiring portion 209b in the direction parallel to the edge portion 21a of the fixation portion 13 on the vibration portion 11 side. The first recess (the recess 215 on the +Y′ side) may include a portion overlapping the wiring portion 209b in plan view.

In this case, for example, since the wiring portion 209b is narrower than the pad portion 209a and is a portion relatively difficult to include a sufficient cross section for the electrical continuity, the effect of improving the reliability of the electrical continuity by the recess 215 is useful. Since the wiring portion 209b overlapping the recess 215 denotes that the wiring portion 209b extends from the vibration portion 11 to the fixation portion 13 over their boundary, this improves the degree of freedom of the position at which the quartz crystal element 201 is fixed to package 103. This configuration, for example, reduces the effect of mounting the quartz crystal element 201 onto the package 103, exerted on the vibration of the vibration portion 11.

### (3.2. Other Examples of Position of Fixation Portion)

FIGS. 9A and 9B are each a plan view of a quartz crystal blank according to other examples. The fixation portion 13 in the embodiment has a shape along one side of the rectangular vibration portion 11. However, the fixation portion may be along two or more sides of the vibration portion. Quartz crystal blanks in FIGS. 9A and 9B include a fixation portion along two or more sides as mentioned above. Specific configurations will be described below.

Note that as already mentioned, the vibration portion 11 is not limited to being rectangular and may be circular or similar in shape. Meanwhile, the term “side” is usually used for a polygon. However, in the description of the embodiment, when the position and the like of a fixation portion 13 relative to a vibration portion 11 is described, the term “side” is used for convenience in some cases. The term “one side” can be rephrased with “an edge portion located on one side in a specified direction relative to a vibration portion 11”. The term “two sides opposed to each other” can be rephrased, for example, with “two edge portions opposed to each other” or “two edge portions of a vibration portion 11 located on both sides in a specified direction”. The term “two sides intersecting each other” can be rephrased, for example, with “two edge portions intersecting each other” or “a combination of the edge portion of a vibration portion 11 located on one side in a first direction and the edge portion of the vibration portion 11 located on one side in a second direction orthogonal to the first direction”.

A quartz crystal blank 303 illustrated in FIG. 9A includes a fixation portion 313 (and an intermediate portion 317) along two sides of a vibration portion 311. In other words, the fixation portion 313 is formed in an L letter shape. Note that instead of the fixation portion 313 being understood to be formed in an L letter shape, the quartz crystal blank 303 may be understood to include two linear fixation portions 313 in total. In the following description, for convenience, a portion of the fixation portion 313 along one side of the vibration portion 311 is sometimes referred to as one side of the fixation portion 313 or a similar term.

Recesses 315 corresponding to the recesses 15 of the embodiment are located, for example, along each of the two sides of the fixation portion 313. However, the recesses 315 may be located on only one side. In the illustrated example, the plurality of recesses 315 are arranged line-symmetrically on each side with respect to the center line of the vibration portion 311 orthogonal to each side. As a matter of course, the arrangement of the recesses 315 may be non-symmetric.

A quartz crystal blank 403 illustrated in FIG. 9B includes a fixation portion 413 (and an intermediate portion 417) along three sides of a vibration portion 411. In other words, the fixation portion 413 is formed in a U letter shape. Note that instead of the fixation portion 413 being understood to be formed in a U letter shape, the quartz crystal blank 403 may be understood to include three linear fixation portions 413 in total. In the following description, for convenience, a portion of the fixation portion 413 along one side of the vibration portion 411 may be referred to as one side of the fixation portion 413 or a similar term.

Recesses 415 corresponding to the recesses 15 of the embodiment are located, for example, along each of the three sides of the fixation portion 413. However, the recesses 415 may be located on only one side or two sides. In the illustrated example, the plurality of recesses 415 are arranged line-symmetrically on each side with respect to the center line of the vibration portion 411 orthogonal to each side. As a matter of course, the arrangement of the recesses 415 can be non-symmetric.

A fixation portion may be located along the four sides of a vibration portion (FIG. 11 described later). As for a quartz crystal element including a fixation portion along two or more sides of a vibration portion, the quartz crystal element may be supported in a manner of a cantilever by only one side fixed to the package 103 as in the embodiment, or the quartz crystal element may be supported by two or more sides fixed to the package 103. The shape and/or dimensions of the fixation portion (and/or the intermediate portion) may be the same between the sides or may be different. For example, the width of the fixation portion on the side including a pad portion 9a (not illustrated) may be larger than the widths of the fixation portions on the other sides. Also in these examples, the portion of the extension electrode overlapping a recess may be a wiring portion or a pad portion, or a configuration in which such distinguishing cannot be made is possible. One side on which a wiring portion extends from the vibration portion to the fixation portion may be different from one side on which a pad portion is located.

### (3.3. Other Examples of Thickness of Fixation Portion)

FIG. 10 is a cross-sectional view of a quartz crystal element 501 according to another example illustrating its configuration and corresponds to part of FIG. 2.

In a quartz crystal blank 503 of the quartz crystal element 501, a fixation portion 513 (and an intermediate portion 517) is higher than a vibration portion 511 on only one side in the thickness direction of the quartz crystal blank 503. Although not illustrated here, recesses corresponding to the recesses 15 are formed only on the one side of the fixation portion 513.

### Chapter 2 Second Embodiment

### 1. Overview of Quartz Crystal Element

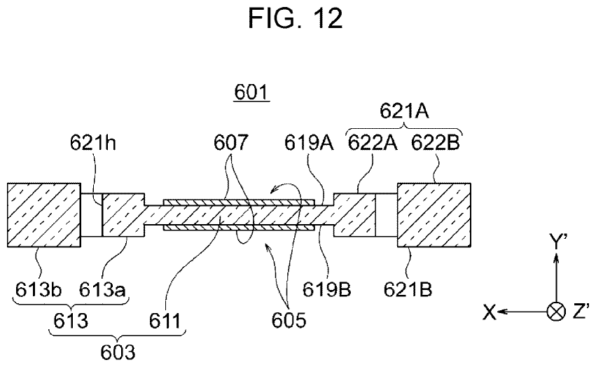

Hereinafter, a quartz crystal element 601 according to a second embodiment will be described with reference to FIGS. 11 and 12. In the following description, basically, only differences from the first embodiment (and other examples according to the first embodiment. The same and/or a similar definition applies to the following.) will be described. Items not referred to may be considered to be the same as and/or similar to those in the first embodiment or may be inferred from the first embodiment. The description of the first embodiment may be applied to the second embodiment unless a contradiction or the like occurs. Note that the description of the second embodiment may be applied to the first embodiment as appropriate. Although the specific configuration of the quartz crystal element 601 may be one other than the one illustrated in FIGS. 11 and 12 as an example, description may be sometimes made on the assumption of the illustrated specific configuration, without specific notation, for convenience.

FIG. 11 is a perspective view of the quartz crystal element 601. FIG. 12 is a cross-sectional view taken along line XII-XII in FIG. 11. The quartz crystal element 601 is, for example, nearly 180-degree rotationally symmetric with respect to the center line (not illustrated. Refer to the center line CL in FIG. 2 according to the first embodiment) parallel to the X axis. Hence, the perspective view of the quartz crystal element 601 from the −Y′ side is the same as and/or similar to the one in FIG. 11.

In FIGS. 11 and 12, the shape of the quartz crystal element 601 is illustrated more schematically than in FIG. 1 illustrating the first embodiment. Specifically, in this figure, illustration of inclined surfaces formed due to the anisotropy of quartz crystal in wet etching is omitted. Hence, illustration of the portion corresponding to the intermediate portion 17 of the first embodiment is omitted, and illustration of inclined surfaces in recesses and through-holes (described later) is also omitted. These portions and inclined surfaces may be present as in the first embodiment. However, a configuration without such portions and inclined surfaces as illustrated in the figure is also possible.

As with the quartz crystal blank 3 of the first embodiment, a quartz crystal blank 603 of the quartz crystal element 601 includes a vibration portion 611 and a fixation portion 613. However, unlike the first embodiment, the fixation portion 613 includes an inner-side portion 613a and outer-side portions 613b which have different thicknesses. The inner-side portion 613a is adjacent to the vibration portion 611 (with or without an intermediate portion (not illustrated) interposed therebetween). Each outer-side portion 613b is located on a side of the inner-side portion 613a opposite to the vibration portion 611 and is thicker than the inner-side portion 613a. In other words, the thickness of the fixation portion 613 changes stepwise such that the further away from the vibration portion 611, the thicker.

This configuration, for example, makes it easy to ensure a sufficient thickness of the outer-side portions 613b. Thus, this configuration improves the effects of the fixation portion 613 being thicker than the vibration portion 611. Examples of the effects include an improvement in the strength of the outer-side portions 613b. If the strength of the outer-side portions 613b is improved, it, for example, reduces the probability of deformation in the quartz crystal blank 603 when the outer-side portions 613b are sucked and held in a manufacturing process. In another viewpoint, the step between the vibration portion 611 and the inner-side portion 613a and the step between the inner-side portion 613a and the outer-side portion 613b can be small. This configuration, for example, reduces the probability of disconnection in the extension electrode 609 at the steps. In addition, for example, the effect of the fixation portion 613 restraining vibration of the vibration portion 611 is lower than in the configuration in which the outer-side portions 613b are connected to the vibration portion 611 without the inner-side portion 613a interposed therebetween, which improves the vibration characteristics.

As mentioned in the section 3.2 of Chapter 1 and other sections, the position of the fixation portion 613 relative to the vibration portion 611 is not particularly limited. In the example in FIG. 11, the fixation portion 613 is located along the four sides of the vibration portion 611 (in another viewpoint, surrounds the vibration portion 611). Thus, the edge portion 621a (corresponding to the edge portion 21a of the first embodiment) of the fixation portion 613 on the vibration portion 611 side is rectangular and forms four recessed corners. A recess 615A corresponding to the first recess 15 of the first embodiment is located at least one (all, in the illustrated example) of the four recessed corners.

In this case, for example, since extension electrodes 609 extend from an excitation electrode 607 to recessed corners, although it depends on the used vibration mode, the effect of the extension electrodes 609 exerted on the vibration is reduced. In addition, a side surface of the recess 615A and a side surface of the inner-side portion 613a that extend in the same direction (the X direction, in the illustrated example) are connected, and thus, the side surface of the recess 615A is substantially extended. This configuration ensures a sufficient area of the electrical continuity of the extension electrode 609 passing via the side surface of the recess 615A, which improves the reliability of the electrical continuity.

The quartz crystal blank 603 includes, in addition to the recesses 615A located between the vibration portion 611 and the fixation portion 613 (the inner-side portion 613a), recesses 615B located between the inner-side portion 613a and the outer-side portions 613b. The effects of this configuration will be described later. Each of the conductor patterns 605 (605A and 605B) of the quartz crystal element 601 includes two extension electrodes 609 on both sides of the excitation electrode 607 in the X direction. The effects of this configuration will also be described later.

The above is a brief description of the differences between the second embodiment and the first embodiment. Each constituent will be described in detail below.

### 2. Quartz Crystal Blank

### (2.1. Whole Quartz Crystal Blank and Vibration Portion)

The description of the whole quartz crystal blank 3 and the vibration portion 11 according to the first embodiment may be applied to the whole quartz crystal blank 603 and the vibration portion 611 according to the second embodiment. Just to be sure, the quartz crystal blank 603 may be, for example, an AT-cut quartz crystal piece as in the first embodiment. The quartz crystal blank 603 and the vibration portion 611 may have any planar shape. The above description of the overview of the second embodiment mentioned that the recesses 615A are formed at the recessed corners of the edge portion 621a (in another viewpoint, the vibration portion 611). However, from the second embodiment, other features may be extracted. In this case, the vibration portion 611 including recessed corners is not requirement. Hence, as mentioned in the description of the first embodiment, the vibration portion 611 may be, for example, circular or elliptical. As mentioned in the description of the first embodiment, in the whole quartz crystal blank 603 or the vibration portion 611, the length in the X direction and the length in the Z′ direction may be the same or different. In the latter case, any one of these lengths may be longer than the other.

Further, just to be sure, the description of the first embodiment mentioned with reference to FIG. 10 that a configuration in which the main surface of the fixation portion 513 on only one side in the thickness direction of the quartz crystal blank 503 is higher than the main surface of the vibration portion 511 is possible. This also can be applied to the second embodiment. However, as already mentioned, the configuration of the quartz crystal blank 603 is sometimes described in this embodiment based on the illustrated example without specific notation, for convenience.

### (2.2. Fixation Portion)

The description of the fixation portion 13 in the first embodiment may be applied to the fixation portion 613 according to the second embodiment. The description of the overview of the second embodiment mentioned that the recesses 615A are formed at the recessed corners of the edge portion 621a. However, from the second embodiment, other features may be extracted. In this case, the fixation portion 613 being located on two sides (four sides in the example of FIG. 11) of the vibration portion 611 is not requirement. Hence, as mentioned in the description of the first embodiment, the fixation portion 613 may be located on, for example, only one side, only two sides, only three sides, or the four sides of the vibration portion 611. The description of the overview of the second embodiment mentioned that the fixation portion 613 includes the inner-side portion 613a and the outer-side portions 613b. However, from the second embodiment, other features can be extracted. In this case, the fixation portion 613 including portions having different thicknesses is not requirement. Hence, for example, the shape of the fixation portion 613 may be the same as and/or similar to the one in the first embodiment.

The following describes the shape of the fixation portion 613 in the configuration including the inner-side portion 613a and the outer-side portions 613b. Just to be sure, even in the configuration in which the fixation portion 613 includes the inner-side portion 613a and the outer-side portions 613b, the description of the fixation portion 13 according to the first embodiment may be applied to the fixation portion 613, unless a contradiction or the like occurs. The description of the fixation portion 13 according to the first embodiment may be applied to the second embodiment by replacing the word “fixation portion 13” with the word “inner-side portion 613a” or “outer-side portion 613b”, unless a contradiction or the like occurs. When the word “fixation portion 13” is replaced with “outer-side portion 613b”, only the word “vibration portion 11” needs to be replaced with the word “vibration portion 611”, or unlike the explanation here, the vibration portion 611 and the inner-side portion 613a may also be considered to correspond to the vibration portion 11 of the first embodiment.

In the following description, of the surface of the quartz crystal blank 603 on the +Y′ side (a first surface 619A and a third surface 621A) and the surface of the quartz crystal blank 603 on the −Y′ side (a second surface 619B (FIG. 12) and a fourth surface 621B), description is sometimes made based on the former as an example, for convenience. The configuration of the surface on the −Y′ side may be, for example, considered to be the same as and/or similar to that of the surface on the +Y′ side.

As already described, the outer-side portions 613b are thicker than the inner-side portion 613a. In another viewpoint, the third surface 621A of the fixation portion 613 includes a first region 622A (the upper surface of the inner-side portion 613a) and second regions 622B (the upper surfaces of the outer-side portions 613b) higher in the +Y′ direction than the first region 622A. The first region 622A includes the edge portion 621a cut in by the recesses 615A already described. The second regions 622B include edge portions 621b cut in by the recesses 615B already described.

The description of the third surface 21A in the first embodiment may be applied to the first region 622A and the second regions 622B, unless a contradiction or the like occurs. Hence, for example, each of the first region 622A and the second regions 622B is a flat plane parallel to the XZ′ plane and/or to the first surface 619A of the vibration portion 611. In other words, the heights of the first region 622A and the second regions 622B differ stepwise (in a step-like manner). Note that from this viewpoint, the fifth surface 23A (in another viewpoint, the intermediate portion 17) illustrated in the description of the first embodiment and the first region 622A (in another viewpoint, the inner-side portion 613a) may be discriminated.

The first embodiment can be considered to be a configuration in which the upper surface of the quartz crystal blank 3 includes a change in one step (more specifically, an increase) from the vibration portion 11 to the fixation portion 13. The second embodiment can be considered to be a configuration in which the upper surface of the quartz crystal blank 603 includes changes in two steps (more specifically, both are increases) from the vibration portion 611 to the fixation portion 613. To express it as a higher-level concept, the second embodiment can be considered to be a configuration in which the upper surface of the quartz crystal blank 603 includes changes in a plurality of steps from the vibration portion 611 to the fixation portion 613 (for example, an increase at every step). The plurality of steps are not limited to two steps but may be three steps or more.

As can be understood from the description above, the inner-side portion 613a may be located on only one side, only two sides, only three sides, or the four sides of the vibration portion 11. In the illustrated example, the inner-side portion 613a is located on the four sides (in another viewpoint, surrounds the vibration portion 611). Also, the outer-side portions 613b may be located on only one side, only two sides, only three sides, or the four sides of the vibration portion 611. In the illustrated example, the outer-side portions 613b are located on two sides opposed to each other in a specified direction with the vibration portion 611 (and the inner-side portion 613a) interposed therebetween (in other words, the outer-side portions 613b include two portions opposed to each other with the vibration portion 611 interposed therebetween). The above specified direction is, more specifically, for example, the X direction (in another viewpoint, the direction of the thickness-shear vibration). In the illustrated example, the entire outer-side portions 613b are connected to the vibration portion 611 with the inner-side portion 613a interposed therebetween, and hence the outer-side portions 613b do not include a portion connected to the vibration portion 611 without the inner-side portion 613a interposed therebetween.

Various kinds of arrangement of the inner-side portion 613a and the outer-side portion 613b in the peripheral direction of the vibration portion 611 are possible, other than the illustrated example. The following describes some examples. For example, the position of the inner-side portion 613a and the outer-side portion 613b may be the same. Specifically, both of the inner-side portion 613a and the outer-side portion 613b may be located on only one side, only two sides, only three sides, or the four sides of the vibration portion 611. For example, contrary to the illustrated example, the arrangement area of the outer-side portion 613b may be larger than the arrangement area of the inner-side portion 613a. For example, a configuration in which an inner-side portion 613a is located on both two sides in the X direction, and an outer-side portion 613b is located on the four sides is possible. In this case, the outer-side portion 613b on both sides in the Z′ direction may be connected to the vibration portion 611 without the inner-side portion 613a interposed therebetween.

In plan view, the relative sizes of the vibration portion 611, the first region 622A, and the second regions 622B are not particularly limited. For example, in the direction in which the first region 622A and second regions 622B are aligned (the X direction, in the illustrated example), the length of the first region 622A and the length of the second regions 622B may be the same or different. When they are different, any one of the length of the former and the length of the latter may be larger than the other. In the alignment direction mentioned above, the length of each of the first region 622A and the second region 622B or the total length on one side (or both sides) of the vibration portion 611 may be the same as or different from the length of the vibration portion 611. When they are different, any one of the length of the former and the length of the latter may be larger than the other. In the illustrated example, in the X direction (the alignment direction mentioned above), the length of the first region 622A is shorter than the length of the second regions 622B. In the X direction, the length of the vibration portion 611 is longer than each of the length of the first region 622A located on one side in the X direction and the length of the second region 622B located on one side in the X direction and is also longer than the total of both. In the X direction, the length of the vibration portion 611 is shorter than the total length of the fixation portion 613 on both sides in the X direction.

Each part of the quartz crystal blank 603 may have any thickness. For example, the thickness of the vibration portion 611 is determined according to the intended resonant frequency as in the first embodiment. As already mentioned, the description of the thickness of the fixation portion 13 mentioned in the first embodiment may be applied to the thickness of the inner-side portion 613a and/or the thickness of the outer-side portions 613b, unless a contradiction or the like occurs. The description of the height from the first surface 19A to the third surface 21A in the first embodiment may be applied to the height from the first surface 619A to the first region 622A and/or the height from the first region 622A to the second regions 622B, unless a contradiction or the like occurs. The relationship between the height from the first surface 619A to the first region 622A and the height from the first region 622A to the second regions 622B (in other words, the relationship between a plurality of heights when the height changes stepwise) is not particularly limited. For example, they may be the same or different. When they are different, any one of the former and the latter may be larger than the other.

### (2.3. Other Information)

As already described above, although illustration is omitted in FIGS. 11 and 12, a portion corresponding to the intermediate portion 17 in the first embodiment may be present between the vibration portion 611 and the fixation portion 613. Specifically, an inclined surface (corresponding to the fifth surface 23A) may be present between the first surface 619A and the third surface 621A (in another viewpoint, the first region 622A or the edge portion 621a). In addition to (or instead of) between the vibration portion 611 and the fixation portion 613, a portion corresponding to the intermediate portion 17 may be present also between the inner-side portion 613a and the outer-side portions 613b (in another viewpoint, between portions adjacent to each other when the thickness changes stepwise). Specifically, an inclined surface (corresponding to the fifth surface 23A) may be present between the first region 622A and the second regions 622B (in another viewpoint, the edge portions 621b).

Again, the description of the intermediate portion 17 according to the first embodiment may be applied to the intermediate portion between the vibration portion 611 and the fixation portion 613, unless a contradiction or the like occurs. In addition, the description of the intermediate portion 17 according to the first embodiment may be applied to the intermediate portion between the inner-side portion 613a and the outer-side portions 613b. In this case, the description of the intermediate portion 17 may be applied, considering the combination of the vibration portion 611 and the inner-side portion 613a as the vibration portion 11, and the outer-side portion 613b as the fixation portion 13. Just to be sure, the intermediate portion in any case may have any inclination angle and may include a flat surface or a non-flat surface.

When the quartz crystal blank 603 is an AT-cut quartz crystal piece, the description of the inclination angle θ1 of the intermediate portion 17 in the first embodiment may be applied to the inclination angle of the intermediate portion located on the +X side or the −X side of the vibration portion 611 (or the inner-side portion 613a). For example, the inclination angle of the intermediate portion on the +X side is approximately 55° (for example, 53° or more and 57° or less). The inclination angle of the intermediate portion on the −X side is approximately 27° (for example, 25° or more and 29° or less). The above description holds true for both surfaces on the +Y′ side and the −Y′ side. The description of the inclination angle θ3 of the first side surface 15b or the inclination angle θ4 of the second side surface 15c may be applied to the inclination angle of the intermediate portion located on the +Z′ side or the −Z′ side of the vibration portion 611 (or the inner-side portion 613a). For example, on the +Y′ surface, the inclination angle of the intermediate portion on the +Z′ side is the same as the inclination angle θ3 and may be approximately 54° (for example, 52° or more and 56° or less) as an example. For example, on the +Y′ surface, the inclination angle of the intermediate portion on the −Z′ side is the same as the inclination angle θ4 and may be approximately 3° (for example, 1° or more and 5° or less) as an example. On the −Y′ surface, contrary to the above, the inclination angle of the intermediate portion on the −Z′ side is the same as the inclination angle θ3, and the inclination angle of the intermediate portion on the +Z′ side is the same as the inclination angle θ4.

The quartz crystal blank 603 may include a through-hole extending through the quartz crystal blank 603 in the thickness direction. The through-hole contribute to, for example, the electrical continuity between the front and back sides (the upper surface and the lower surface) of the quartz crystal blank 603 and/or reducing the probability that vibration leaking from the regions where the excitation electrode 607 are located propagates toward the fixation portion 613 side. The position, shape, and dimensions of the through-hole may be determined as appropriate depending on the purpose and other factors.

In the example of FIG. 11, through-holes 621h located between the inner-side portion 613a and the outer-side portions 613b are illustrated as an example. Part or all (in the illustrated example, all) of the through-hole 621h is located, for example, between the extension electrodes 609 (more specifically, the pad portions 609a) aligned in the Z′ direction. The length of the through-hole 621h in the Z′ direction is longer than the length in the X direction. In plan view (in another viewpoint, in the X direction), the through-hole 621h may be situated within the intermediate portion, illustration of which is omitted, between the inner-side portion 613a and the outer-side portion 613b or may extend into the inner-side portion 613a and/or the outer-side portion 613b. The meaning of the expression “the through-hole 621h is located between the inner-side portion 613a and the outer-side portion 613b” includes cases in which the through-hole 621h is situated in a portion of the inner-side portion 613a on the outer-side portion 613b side, cases in which the through-hole 621h is situated in a portion of the outer-side portion 613b on the inner-side portion 613a side, and cases in which the through-hole 621h is situated over both portions. The through-holes 621h contribute, for example, the electrical continuity between the front and back sides and reduction of propagation of leaked vibration.

Note that in the illustrated example, through-holes are not formed between the vibration portion 611 and the fixation portion 613 (the inner-side portion 613a). In another viewpoint, through-holes are not formed in the regions of the vibration portion 611 and the inner-side portion 613a (except the outer edges of the inner-side portion 613a). This configuration, for example, improves the strength of the portions mentioned above. However, instead of or in addition to the through-holes 621h, through-holes 621h may be located between the vibration portion 611 and the fixation portion 613 (the inner-side portion 613a). These through-holes may contribute to, for example, the electrical continuity between the front and back sides and reduction of propagation of leaked vibration, as with the through-holes 621h. Although not illustrated, circular through-holes may be formed in the regions of the outer-side portions 613b where the pad portions 609a are located, or through-holes with an appropriate shape may be formed between the two pad portions 609a on the outer-side portions 613b.

### 3. Conductor Pattern

As with each conductor pattern 5 of the first embodiment, each of the conductor patterns 605 (605A and 605B) includes the extension electrode 609 extending toward a portion of the fixation portion 613 located on the +X side of the vibration portion 611. With this configuration, the pad portions 609a of the extension electrodes 609 on the +X side are joined to the pads 111 with the bumps 105, as in the first embodiment and as described with reference to FIG. 7, so that the quartz crystal element 601 is supported in a manner of a cantilever and mounted on the package 103.

Unlike each conductor pattern 605 of the first embodiment, each of the conductor patterns 605 (605A and 605B) further includes the extension electrode 609 extending toward a portion of the fixation portion 613 located on the −X side of the vibration portion 611. This configuration enables, for example, any of the +X side and the −X side of the quartz crystal element 601 to serve as the fixed end side in a configuration supported in a manner of a cantilever. This configuration also enables, for example, the quartz crystal element 601 to be supported at both ends by two pad portions 609a located at both ends or to be supported at both ends by the four pad portions 609a located at both ends, instead of being supported in a manner of a cantilever.

As a matter of course, as clearly understood from the explanation that the description of the first embodiment may be applied to the second embodiment, each conductor pattern 605 may include only one extension electrode 609. In this case, as in the first embodiment, for example, the two conductor patterns 605 each may include an extension electrode 609 on only one of the +X side and the −X side. Alternatively, unlike the first embodiment, a configuration in which one of the conductor patterns 605 includes an extension electrode 609 on the +X side, and the other of the conductor patterns 605 includes an extension electrode 609 on the −X side is possible.

In addition, at least one extension electrode 609 (a pad portion 609a) of each conductor pattern 605 may include a configuration not illustrated in the figures. For example, two pad portions 609a of one conductor pattern 605 may be located in a portion of the fixation portion 613 located on one side of the vibration portion 611 in the X direction and in a portion of the fixation portion 613 located on one side of the vibration portion 611 in the Z′ direction.

As mentioned in the description of the first embodiment, a pad portion 609a of each extension electrode 609 may be located on both or one of the +Y′ side and the −Y′ side. FIG. 11 illustrates an example of the former case.

In each conductor pattern 605, two extension electrodes 609 extending on the sides opposite to each other in the X direction may extend on the same side in the Z′ direction (the illustrated example) or may extend on the sides opposite to each other in the Z′ direction. In the former case, when the quartz crystal element 601 is mounted on the package 103 by using two pad portions 609a on both ends out of the four pad portions 609a at the four corners, two pad portions 609a located at a pair of opposed corners are used for mounting. In this case, for example, the center of gravity of the quartz crystal element 601 is apt to be located on the line connecting the two pad portions 609a, which stabilizes the support of the quartz crystal element 601.

The relationship (the relationship on the positions, shapes, sizes, and the like. The same and/or a similar definition is applied to the following) between each portion of the extension electrode 609 (the pad portion 609a and the wiring portion 609b) and each portion of the quartz crystal blank 603 (the vibration portion 611, the fixation portion 613, the inner-side portion 613a, and the outer-side portions 613b) is not particularly limited. In the illustrated example, the wiring portion 609b extends from the excitation electrode 607 over the edge portion 621a to a halfway position in the inner-side portion 613a. The pad portion 609a expands from the halfway position in the inner-side portion 613a over the outer-side portion 613b. In this case, for example, even though the pad portions 609a which are fixed to the package 103 and affect the vibration is away from the vibration portion 611, a sufficient area for the electrical continuity can be ensured by the pad portions 609a at the steps between the inner-side portion 613a and the outer-side portions 613b.

Again, the description related to the relationship between each portion of the extension electrode 9 and each portion of the quartz crystal blank 3 in the first embodiment may be applied to that in the second embodiment, unless a contradiction or the like occurs. In this case, in terms of the example of FIG. 11, the vibration portion 611 and the inner-side portion 613a may be considered to correspond to the vibration portion 11, and the outer-side portion 613b may be considered to correspond to the fixation portion 13. In addition, the description related to the positional relationship between each portion of the extension electrode 209 and each portion of the quartz crystal blank (the symbol of which is omitted) illustrated in FIG. 8 as an example may be applied to that in the second embodiment, unless a contradiction or the like occurs. In this case, in terms of the example of FIG. 11, the vibration portion 611 may be considered to correspond to the vibration portion 11, and the fixation portion 613 may be considered to correspond to the fixation portion 13.

Examples of configurations different from the illustrated example include a configuration in which a pad portion 609a extends over the edge portion 621a of the fixation portion 613 on the vibration portion 611 side to the outer periphery of the vibration portion 611, as in the first embodiment. Note that in another viewpoint, this configuration is one in which description of the first embodiment is simply applied to the second embodiment. An example of another configuration is one in which a wiring portion 609b extending from the excitation electrode 607 extends over the inner-side portion 613a to the outer-side portion 613b.

As in the illustrated example, in a configuration in which the edge portion of the pad portion 609a on the vibration portion 611 side is located on the inner-side portion 613a, the specific position of the edge portion mentioned above is not particularly limited. For example, the edge portion mentioned above may be located at a halfway position between the edge portion 621a and the edge portion 621b (or the edge portion, on the inner-side portion 613a side, of the intermediate portion (not illustrated) adjacent to the edge portion 621b) or may be located on the vibration portion 611 side or the outer-side portion 613b side of the halfway position mentioned above.

As mentioned in the description of the first embodiment, the specific position, shape, size, and the like of the wiring portion 609b are not particularly limited. In the illustrated example, a wiring portion 609b extends linearly from the excitation electrode 607 toward one of the four recessed corners formed by the edge portion 621a (in another viewpoint, the vibration portion 611). Then, the wiring portion 609b extends from the recessed corner in the X direction to the pad portion 609a. Examples of configurations different from the illustrated example include one in which the entire wiring portion 609b extends in the X direction, one in which the entire wiring portion 609b linearly extends obliquely relative to the X direction, and one in which the bent position is located on the vibration portion 611 side or the inner-side portion 613a side of the recessed corner.

### 4. Recess

The recesses 615A and 615B are the same as and/or similar to the recesses 15 except their specific positions. Hence, again, the description of the recesses 15 may be applied to the recesses 615A and 615B, unless a contradiction or the like occurs. Hence, for example, the number of recesses 615A and recesses 615B that overlap one extension electrode 609 and other factors may be determined as appropriate.

In the illustrated example, a plurality of recesses 615B is arranged along the edge portion 621b and overlaps the pad portions 609a. This configuration is similar to that of the recesses 15 in the first embodiment. Hence, for example, considering that the vibration portion 611 and the inner-side portion 613a correspond to the vibration portion 611 of the first embodiment and that the outer-side portion 613b corresponds to the fixation portion 13 of the first embodiment, the description of the number and positions of recesses 15 in the first embodiment and the positional relationship between the recesses 15 and the extension electrode 9 may be applied to the recesses 615B.

In the following description, the recesses 615A will be described based on the surface on the +Y′ side as an example, for convenience. The surface on the −Y′ side is the same and/or similar.

In the illustrated example, as already described, the recesses 615A are located at the recessed corners formed by the edge portion 621a. More specifically, the edge portion 621a includes four partial edge portions 621aa located on the +X side, the −X side, the +Z′ side, and the −Z′ side of the vibration portion 611 and includes four recessed corners. A recess 615A is located at each of the four recessed corners. In other words, a recess 615A is located at a corner formed by two partial edge portions 621aa intersecting each other.

The expression “a recess 615A is located at a recessed corner (or a recessed corner of the edge portion 621a is cut out)” or a similar expression suggests unless otherwise noted that the recess 615A may have a shape in which only one or both of two partial edge portions 621aa forming the recessed corner are cut in. In the illustrated example, the recesses 615A each have a shape in which the partial edge portion 621aa on the +X side or the −X side of the vibration portion 611 is cut in and that the partial edge portion 621aa on either the +Z′ side or the −Z′ side of the vibration portion 611 is not cut in. In a configuration in which a recess 615A has a shape in which only one of two partial edge portions 612aa is cut in, the partial edge portion 621aa on the +Z′ side or the −Z′ side may be cut in, unlike the illustrated example.

The expression “a recess 615A is located at a recessed corner (or a recessed corner of the edge portion 621a is cut out)” or a similar expression suggests that the recess 615A may overlap the intersection point of the two partial edge portions 621aa forming the recessed corner mentioned above (when the intersection point is cut out by the presence of the recess 615A, the intersection point refers to the imaginary point obtained by extending the two partial edge portions 621aa) or may be a relatively short distance away from the intersection point mentioned above, unless otherwise noted. Note that as a matter of course, the recess 615A may be away from the intersection point mentioned above by a distance in a degree of manufacturing variations. The short distance mentioned above, regardless of whether it is a manufacturing variation, may be, for example, ½ or less, ⅓ or less, or ⅕ or less of the width w1 of the recess 615A (see FIG. 3) or may be, for example, 10 μm or less, 5 μm or less, or 1 μm or less.

Note that when a recessed corner (or a corner) is cut out by the presence of the recess 615A, a concept or expression that the recessed corner is not present might be possible. However, the present disclosure does not take such a concept or expression, for convenience. Even if a recessed corner is cut out by the presence of the recess 615A, it is easily understood by extending the partial edge portions 621aa extending in directions intersecting each other that a corner (a recessed corner) would be present if the recess 615A were not formed.

The recess 615A may have any shape and dimensions regardless of which of the two partial edge portions 621aa forming the recessed corner is cut in. For example, the planar shape of the recess 615A may be rectangular, triangular, or semicircular as mentioned in the first embodiment. For example, in a configuration in which the recess 615A has a shape in which only one partial edge portion 621aa is cut in, the description of the first embodiment may be directly applied to the shape and dimensions of the recess 615A in plan view. For example, in a configuration in which the recess 615A has a shape in which two partial edge portions 621aa are cut in, the shape of the recess 615A in plan view may be one having its horizontal depth in the direction of the straight line (for example, a diagonal line) that bisects the angle formed by the two partial edge portions 621aa or one having its horizontal depth in the direction orthogonal to one partial edge portion 621aa and having its width protruding into the other edge portion 621a. The direction in which the width w1 and the horizontal depth d1 are measured, mentioned in the description of the first embodiment can be judged rationally from the shape of the recess 615A. When the recess 615A has a shape in which two partial edge portions 621aa are cut in, and the value of the horizontal depth d1 differs depending on which partial edge portion 621aa is used for the reference, the maximum horizontal depth may be regarded as the horizontal depth d1, as in the first embodiment.

As in the illustrated example, in a configuration in which the recess 615A has a shape in which only the partial edge portion 621aa located on the +X side or the −X side of the vibration portion 611 is cut in, the direction in which the edge portion is cut in is the same as that of the first recess 15 of the first embodiment. Hence, the description of the inclination angles when the side surfaces of the recess 15 include crystal planes may be directly applied to the inclination angles when the side surfaces of the recess 615A include crystal planes. Unlike the illustrated example, in a configuration in which the recess 615A has a shape in which only a partial edge portion 621aa located on the +Z′ side or the −Z′ side of the vibration portion 611 is cut in, the description of the inclination angles in the first embodiment may be applied to the configuration as appropriate in consideration of the relationship between each side surface and the Cartesian coordinate system XY′Z′. For example, the description of the inclination angle θ2 of the third side surface 15d may be applied to the inclination angle of a side surface on the +X side or the −X side. The description of the inclination angle θ3 of the first side surface 15b may be applied to the inclination angle of a side surface on the +Z′ side. The description of the inclination angle θ4 of the second side surface 15c may be applied to the inclination angle of a side surface on the −Z′ side.

In the illustrated example, the recess 615A has a shape in which only one of the two partial edge portions 621aa (more specifically, the partial edge portion 621aa located on the +X side or the −X side of the vibration portion 611) is cut in. Then, an upper-surface edge portion (an edge portion at the height of the first region 622A) of the recess 615A is connected approximately in a straight line to the partial edge portions 621aa not cut in. In another viewpoint, the side surface of the recess 615A on the +Z′ side or the −Z′ side is connected, so as to form approximately the same plane, to the side surface, on the vibration portion 611 side, of the portion of the inner-side portion 613a located on the +Z′ side of the vibration portion 611 (in another viewpoint, an inclined surface of the intermediate portion (not illustrated)) or the side surface, on the vibration portion 611 side, of the portion of the inner-side portion 613a located on the −Z′ side of the vibration portion 611 (in another viewpoint, an inclined surface of the intermediate portion (not illustrated). This is a point different from the shape of the recess 15 not located at a recessed corner. Note that unlike the illustrated example, the upper-surface edge portion of the recess 615A may be connected to the partial edge portion 621aa such that these portions intersect each other so as to form a corner and/or such that at least one of these portions is curved at the connection point, instead of these portions being connected to each other in a straight line.

The recesses 615A are formed at the four recessed corners of a rectangular shape, as already described. In other words, the four recesses 615A are located to be line-symmetric with respect to the center line (not illustrated) of the vibration portion 611 (or the excitation electrode 607) parallel to the X direction. The four recesses 615A are also located to be line-symmetric with respect to the center line of the vibration portion 611 (or the excitation electrode 607) parallel to the Z′ direction. As mentioned in the first embodiment, the shapes and dimensions of the plurality of recesses 615A may be the same as or different from one another.

In the illustrated example, two of the four recesses 615A overlap the extension electrodes 609. As mentioned in the description of the first embodiment, the recesses 615A may be formed at only the positions where the recesses 615A overlap the extension electrodes 609. Hence, for example, on the +Y′ side face, a configuration in which the two recesses 615A on the +Z′ side are not formed, and only the two recesses 615A on the −Z′ side are formed is possible. For example, unlike the illustrated example, in a configuration in which the first conductor pattern 605A includes only one extension electrode 609, only one recess 615A may be formed. As clearly understood from the description of the conductor pattern 605, the recess 615A overlaps the wiring portion 609b out of the extension electrode 609. Again, for example, the description of the wiring portion 209b and the recess 215 with reference to FIG. 10 may be applied to the wiring portions 609b and the recess 615A, unless a contradiction or the like occurs.

When the description related to the vertical depth of the recess 15 according to the first embodiment is applied to the recess 615A, for example, the word “third surface 21A” may be replaced with the word “first region 622A”, unless a contradiction or the like occurs. When the description related to the vertical depth of the recess 15 according to the first embodiment is applied to the recess 615B, for example, the word “third surface 21A” may be replaced with the word “second region 622B”, and the word “first surface 19A” may be replaced with the word “first surface 619A” and/or “first region 622A”, unless a contradiction or the like occurs. Meanwhile, the word “thickness of the vibration portion 11” is not replaced unless a contradiction or the like occurs and/or may be replaced with the word “inner-side portion 613a”.

The first embodiment indicated as a specific example that the height h1 from the first surface 19A to the third surface 21A is 16 μm or less or 12 μm or less. As mentioned above, this range may be applied to the height from the first surface 619A to the first region 622A in the second embodiment, the height from the first region 622A to the second regions 622B, and/or the height from the first surface 619A to the second regions 622B. However, in the second embodiment, setting the height of one step small is easier than in the first embodiment, as already described. Hence, the height (the height h1) of one step indicated as an example in the description of the first embodiment can be smaller in the second embodiment. For example, the height from the first surface 619A to the first region 622A and/or from the height from the first region 622A to the second regions 622B may be set to 8 μm or less or 6 μm or less, which are half of the values mentioned above.

### 5. Method of Manufacturing Quartz Crystal Element

The method of manufacturing the quartz crystal element 601 may be, for example, nearly the same as and/or similar to the method of manufacturing the quartz crystal element 1 according to the first embodiment. The stepwise change in the thickness of the fixation portion 613 may be formed, for example, by increasing the number of processes in which etching is performed with an etching mask formed on the quartz crystal blank 603.

Specifically, for example, the quartz crystal blank 603 is first etched through an etching mask having a shape the same as and/or similar to the planar shape of the quartz crystal blank 603 as in the first embodiment. Then, etching is performed through an etching mask having a shape the same as and/or similar to the planar shape of the fixation portion 613. Then, etching is performed through an etching mask having a shape the same as and/or similar to the planar shape of the outer-side portions 613b. These processes form the vibration portion 611, the inner-side portion 613a thicker than the vibration portion 611, and the outer-side portions 613b thicker than the inner-side portion 613a.

### 6. Summary of Quartz Crystal Element

As described above, also in the second embodiment, the quartz crystal element 601 includes a piezoelectric blank (the quartz crystal blank 603), a first excitation electrode (for example, the excitation electrode 607 of the first conductor pattern 605A), and a first extension electrode (for example, the extension electrode 609 of the first conductor pattern 605A). The quartz crystal blank 603 includes the vibration portion 611 and the fixation portion 613 including different regions in plan view. The vibration portion 611 includes the first surface 619A facing a first side (the +Y′ side) and the second surface 619B facing a second side (the −Y′ side) opposite to the first side. The fixation portion 613 includes the third surface 621A facing the +Y′ side and the fourth surface 621B facing the −Y′ side. The third surface 621A is higher than the first surface 619A in the +Y′ direction. The excitation electrode 607 overlies the first surface 619A. The extension electrode 609 is extended from the excitation electrode 607 and overlies the third surface 621A. The quartz crystal blank 603 includes a first recess (the recess 615A on the +Y′ side) recessed from the third surface 621A toward the −Y′ side. The recess 615A has a shape in plan view in which a first edge portion (the edge portion 621a) of the third surface 621A on the first surface 619A side is cut in. The extension electrode 609 includes a portion extending from the first surface 619A via the recess 615A to the third surface 621A.

Hence, for example, the second embodiment provides effects the same as and/or similar to those of the first embodiment. Specifically, for example, the recesses 615A improve the reliability of the electrical continuity of the extension electrode 609. In addition, for example, while a sufficient strength of the fixation portion 613 is ensured as a whole, the stiffness of part of the fixation portion 613 on the vibration portion 611 side is reduced, so that the strain exerted by the bumps 105 (FIG. 7) on the fixation portion 613 is absorbed by the recesses 615A, which reduces the probability of deterioration in vibration characteristics. In addition, this configuration, for example, reduces the probability that the waves having traveled from the vibration portion 611 to various positions in the edge portion of the fixation portion 613 are reflected in the same direction in the same phase, which reduces the probability that reflected waves act as noises.

In the second embodiment, the first edge portion (the edge portion 621a) includes a first partial edge portion (for example, the partial edge portion 621aa on the +X side) and a second partial edge portion (for example, the partial edge portion 621aa on the −Z′ side). In plan view, the first partial edge portion is located on one side (the +X side) of the vibration portion 611 in a first direction (for example, the X direction). In plan view, the second partial edge portion is located on one side (for example, the −Z′ side) of the vibration portion 611 in a second direction (for example, the Z′ direction) orthogonal to the first direction and, along with the first partial edge portion, forms a recessed corner. The first recess (the recess 615A) has a shape in which at least one of the first partial edge portion and the second partial edge portion is cut in at the recessed corner mentioned above.

In this case, as mentioned in the description of the overview of the second embodiment (chapter 2, the first section), for example, since the extension electrodes 609 extend from the excitation electrode 607 to recessed corners, although it depends on the used vibration mode, the effect of the extension electrodes 609 exerted on the vibration is reduced. In addition, since a side surface of the recess 615A and a side surface of the inner-side portion 613a which extend in the same direction (the X direction, in the illustrated example) are connected, the side surface of the recess 615A is substantially extended. Thus, a sufficient area of the electrical continuity of the extension electrode 609 extending via the side surface of the recess 615A is ensured, which improves the reliability of the electrical continuity.

The third surface 621A may include the first region 622A and the second regions 622B. The first region 622A includes the first edge portion (the edge portion 621a) mentioned above. Each second region 622B is located on the side of the first region 622A opposite to the first surface 619A in plan view and is higher than the first region 622A in the direction of the first side (the +Y′ side). The first extension electrode (for example, the extension electrode 609 of the first conductor pattern 605A on the +X side) may extends via the first region 622A to the second region 622B.

In this case, for example, as mentioned in the description of the overview of the second embodiment, this configuration makes it possible to set the height from the first surface 619A to the first region 622A low and reduce the probability of disconnection at the edge portion 621a, while ensuring a sufficient thickness (in other words, strength) of the outer-side portions 613b. For example, the effect of the fixation portion 613 restraining the vibration of the vibration portion 611 is lower than in a configuration in which the outer-side portions 613b are connected to the vibration portion 611 without the inner-side portion 613a interposed therebetween, which improves the vibration characteristics.

The piezoelectric blank (the quartz crystal blank 603) may include a second-region recess (recesses 615B) recessed from the second region 622B toward the second side (for example, the −Y′ side). The recess 615B may have a shape in plan view in which the second-region edge portion (the edge portion 621b) of the second region 622B on the first region 622A side is cut in. The first extension electrode (for example, the extension electrode 609 of the first conductor pattern 605A on the +X side) may extend from a first recess (a recess 615A) via the recesses 615B and to the second region 622B.

In this case, for example, not only the probability of disconnection at the edge portion 621a is reduced by the recesses 615A, but also the probability of disconnection at the edge portion 621b is reduced by the recesses 615B. Thus, this configuration increases the reliability of the electrical continuity of the extension electrode 609 as a whole.

The first extension electrode (for example, the extension electrode 609 of the first conductor pattern 605A on the +X side) may include the wiring portion 609b and the pad portion 609a. The wiring portion 609b may extend from the first excitation electrode (the excitation electrode 607 of the first conductor pattern 605A) and pass a first recess (a recess 615A). The pad portion 609a may include a portion overlapping the second region 622B, and may be wider than the wiring portion 609b in the direction parallel to the first edge portion (the edge portion 621a).

In this case, for example, the pad portions 609a that are fixed to the package 103 and affect the vibration are located away from the vibration portion 611. In the configuration in which the wiring portion 609b passes the recess 615A, the area of electrical continuity is smaller than in the configuration in which the pad portion 609a overlaps the recess 615A. However, the height from the first surface 619A to the first region 622A is low as mentioned above, which reduces the probability of disconnection. Hence, the reliability of the electrical continuity is improved as a whole, and the vibration characteristics are improved.

The first region 622A may surround the vibration portion 611 in plan view. A possible configuration may be such that the second region 622B is located on one side or both sides of the vibration portion 611 and the first region 622A in the first direction (for example, the X direction) in plan view and is not located either side of the vibration portion 611 and the first region 622A in the second direction (for example, the Z′ direction).

In this case, for example, the effects of the second regions 622B, which have a relatively high strength, exerted on the vibration of the vibration portion 611 are lower than in the configuration in which the vibration portion 611 is surrounded by the second regions 622B (this configuration is also included in the technology according to the present disclosure). On the other hand, the probability that the vibration portion 611 is deformed by a shock or the like can be lower than the configuration in which the vibration portion 611 is not surrounded by the first region 622A (this configuration is also included in the technology according to the present disclosure). Hence, this configuration improves the vibration characteristics while improving the strength as a whole.

The piezoelectric blank (the quartz crystal blank 603) may include the through-holes 621h extending through the quartz crystal blank 603 in the thickness direction between the first region 622A and the second regions 622B.

This, for example, makes it easier to achieve the electrical continuity of the front and back sides and/or reduces propagation of leaked vibration, as already described. This configuration makes it easier to improve the strength of the portion consisting of the vibration portion 611 and the inner-side portion 613a (the portion relatively thin) than in the configuration in which the through-holes are located between the vibration portion 611 and the first region 622A (the inner-side portion 613a).

The quartz crystal element 601 may further include a second excitation electrode (for example, the excitation electrode 607 on the −Y′ side), a second extension electrode (for example, the extension electrode 609 of the second conductor pattern 605B on the +X side), a third extension electrode (for example, the extension electrode 609 of the first conductor pattern 605A on the −X side), and a fourth extension electrode (for example, the extension electrode 609 of the second conductor pattern 605B on the −X side). The second excitation electrode may overlie the second surface 619B. The second extension electrode may be extended from the second excitation electrode and overlie the fourth surface 621B. The third extension electrode may be extended from the first excitation electrode (for example, the excitation electrode 607 on the +Y′ side) in a direction different from that of the first extension electrode (the extension electrode 609 of the first conductor pattern 605A on the +X side) and overlie the third surface 621A. The fourth extension electrode may be extended from the second excitation electrode in a direction different from that of the second extension electrode and overlie the fourth surface 621B. The fixation portion 613 may surround the vibration portion 611 in plan view. The first extension electrode may include a portion located on a first partial edge portion side (for example, the +X side partial edge portion 621aa side) and on a second partial edge portion side (for example, the −Z′ side partial edge portion 621aa side) of the first excitation electrode. The second extension electrode may include a portion located on a first partial edge portion side (the +X side) of the second excitation electrode and on the side (the +Z′ side) of the second excitation electrode opposite to the second partial edge portion. The third extension electrode may include a portion located on the side (the −X side) of the first excitation electrode opposite to the first partial edge portion side and on the second partial edge portion side (the −Z′ side) of the first excitation electrode. The fourth extension electrode may include a portion located on the side (the −X side) of the second excitation electrode opposite to the first partial edge portion and on the side (the +Z′ side) of the second excitation electrode opposite to the second partial edge portion.

This enables, for example, various mounting configurations as already described. Since the arrangement of the conductor patterns 605 is symmetric with respect to the center line parallel to the X direction and the center line parallel to the Z′ direction, the electrical and/or mass-wise effects of the conductor patterns 605 exerted on the vibration of the quartz crystal blank 603 are apt to be symmetric. Thus, the probability of occurrence of unintended unusual vibration is reduced. This in turn improves the characteristics of the quartz crystal element 601.

The first edge portion (the edge portion 621a) may include a third partial edge portion (for example, the partial edge portion 621aa on the −X side) and a fourth partial edge portion (for example, the partial edge portion 621aa on the +Z′ side). The third partial edge portion may face the first partial edge portion (for example, the partial edge portion 621aa on the +X side) with the vibration portion 611 interposed therebetween. The fourth partial edge portion may face the second partial edge portion (for example, the partial edge portion 621aa on the −Z′ side) with the vibration portion 611 interposed therebetween. In plan view, the piezoelectric blank (the quartz crystal blank 603) may include the four recesses 615A in total, including the first recess, at the four recessed corners formed by the first partial edge portion, the second partial edge portion, the third partial edge portion, and the fourth partial edge portion, each recess having a shape that is recessed from the third surface 621A toward the second side (the −Y′ side) and in which the edge portion 621a is cut in.

In this case, the recesses 615A are located line-symmetric with respect to the center line of the vibration portion 611 parallel to the X direction and line-symmetric with respect to the center line of the vibration portion 611 parallel to the Z′ direction. Hence, the effects of the recesses 615A exerted on the vibration of the vibration portion 611 are apt to be symmetric. Thus, the probability of occurrence of unintended unusual vibration is reduced. This in turn improves the characteristics of the quartz crystal element 601.

In the second embodiment described above, the quartz crystal element 601 is an example of a piezoelectric vibration element. The quartz crystal blank 603 is an example of a piezoelectric blank. The +Y′ side is an example of the first side. The −Y′ side is an example of the second side. The excitation electrode 7 of the first conductor pattern 605A is an example of the first excitation electrode. The excitation electrode 7 of the second conductor pattern 605B is an example of the second excitation electrode. The extension electrode 9 of the first conductor pattern 605A on the +X side is an example of the first extension electrode. The extension electrode of the second conductor pattern 605B on the +X side is an example of the second extension electrode. The extension electrode 9 of the first conductor pattern 605A on the −X side is an example of the third extension electrode. The extension electrode of the second conductor pattern 605B on the −X side is an example of the fourth extension electrode. The edge portion 621a on the +Y′ side is an example of the first edge portion. The edge portion 621a on the −Y′ side is an example of the second edge portion. The recesses 615A on the +Y′ side are an example of the first recess. The recesses 615A on the −Y′ side are an example of the second recess. The partial edge portion 621aa on the +X side is an example of the first partial edge portion. The partial edge portion 621aa on the −Z′ side is an example of the second partial edge portion. The partial edge portion 621aa on the −X side is an example of the third partial edge portion. The partial edge portion 621aa on the +Z′ side is an example of the fourth partial edge portion. The edge portions 621b are an example of the second-region edge portion. The recesses 615B are an example of the second-region recess.

The technology according to the present disclosure is not limited to the embodiments and the like described above and may be implemented in various configurations.

The aforementioned embodiments and their various examples may be combined as appropriate. For example, the configuration illustrated in FIG. 10 in which the fixation portion is higher than the vibration portion only on one side in the thickness direction may be applied to the configurations including the fixation portion extending along two or more sides, illustrated in FIGS. 9A and 9B as examples. The through-holes illustrated in the second embodiment may be applied to the first embodiment. The recesses that the extension electrodes do not overlap, illustrated in the second embodiment may be applied to the first embodiment. As mentioned in the second embodiment, the piezoelectric blank need not include an intermediate portion the thickness of which changes, between the fixation portion and the vibration portion, and the same and/or a similar configuration may be applied to the first embodiment.

The piezoelectric material is not limited to quartz crystal. For example, the piezoelectric material may be another single crystal material or a polycrystalline material (for example, a ceramic). The piezoelectric material is not limited to ones using the fundamental wave vibration of thickness-shear vibration and may be ones using another vibration mode or ones using an overtone vibration. In addition, the piezoelectric material may be one using elastic waves that are excited through excitation electrodes formed only on the first surface (or the second surface). Cutting of a quartz crystal blank using thickness-shear vibration is not limited to AT-cut. For example, it may be BT-cut. The quartz crystal blank is not limited to ones composed of only quartz crystal, and examples include ones composed of quartz crystal infused with a dopant of a metal or the like.

The piezoelectric vibration element may be mounted by means other than the use of two conductive bumps. For example, a possible configuration may be such that a pad portion of one extension electrode located on the lower surface of the fixation portion is joined to a pad of the package with one conductive bump, and a pad portion of one extension electrode located on the upper surface of the fixation portion is coupled to a pad of the package with one bonding wire. Another possible configuration may be such that the lower surface of the fixation portion is joined to the package with an insulating adhesive, and pad portions of two extension electrodes located on the upper surface of the fixation portion are coupled to two pads of the package with two bonding wires.

From the present disclosure, configurations of a piezoelectric vibration element in which a first recess (a recess 615A) being located at a recessed corner of a vibration portion is not a requirement can be extracted. A piezoelectric vibration element in such a configuration may be, for example, characterized in that the thickness of a fixation portion changes stepwise or characterized in that one excitation electrode includes two extension electrodes.

From the present disclosure, configurations of a piezoelectric vibration element can be extracted in which, when the size of the first recess (for example, the recess 15 on the +Y′ side) in the direction parallel to the first edge portion (21a) is referred to as the width of the first recess, a side surface (for example, the first side surface 15b) including an inclined surface inclined in such an orientation that the width of the first recess increases toward the first side (the +Y′ side) and extending from the bottom portion of the first recess to the third surface (21A) is not a requirement, and in which the extension electrode (9) including a portion extending from the bottom portion of the first recess via the inclined surface mentioned above to the third surface mentioned above is not a requirement. A piezoelectric vibration element in such a configuration may be, for example, characterized in that the width and/or the horizontal depth of the recess are larger than those of a specified portion, characterized in that the bottom surface (15a) of the recess protrudes from the edge portion (21a) of the third surface toward a third surface side, characterized in that the wiring portion (9b) of the extension electrode overlaps at least part of the recess, or characterized in that a side surface of the recess includes a crystal plane.

The following concepts can be extracted from the present disclosure.

### (Concept 1)

A piezoelectric vibration element including:
a piezoelectric blank including a vibration portion and a fixation portion including different regions in plan view,
   the vibration portion including:
      a first surface facing a first side; and
      a second surface facing a second side opposite to the first side,
   the fixation portion including:
      a third surface facing the first side; and
      a fourth surface facing the second side,
   the third surface being higher than the first surface in a direction of the first side;
a first excitation electrode overlying the first surface; and
a first extension electrode extended from the first excitation electrode and overlying the third surface, wherein the piezoelectric blank includes a first recess recessed from the third surface toward the second side,
the first recess has a shape in plan view in which a first edge portion of the third surface on a first surface side is cut in,
the first extension electrode includes a portion extending from the first surface via the first recess to the third surface,
the first edge portion includes:
   a first partial edge portion located on one side of the vibration portion in a first direction in plan view; and
   a second partial edge portion located on one side of the vibration portion in a second direction orthogonal to the first direction in plan view and, along with the first partial edge portion, forming a recessed corner, and
the first recess has a shape in which at least one of the first partial edge portion and the second partial edge portion is cut in at the recessed corner.

### (Concept 2)

The piezoelectric vibration element according to concept 1, in which
the third surface includes:
   a first region including the first edge portion; and
   a second region located on a side of the first region opposite to the first surface in plan view and being higher than the first region in the direction of the first side, and
the first extension electrode extends via the first region to the second region.

### (Concept 3)

The piezoelectric vibration element according to concept 2, in which
the piezoelectric blank includes a second-region recess recessed from the second region toward the second side,
the second-region recess has a shape in plan view in which a second-region edge portion of the second region on a first region side is cut in, and
the first extension electrode extends from the first recess via the second-region recess to the second region.

### (Concept 4)

The piezoelectric vibration element according to concept 2 or 3, in which
the first extension electrode includes:
   a wiring portion extending from the first excitation electrode and passing the first recess; and
   a pad portion including a portion overlapping the second region and being wider than the wiring portion in a direction parallel to the first edge portion.

### (Concept 5)

The piezoelectric vibration element according to any one of concepts 2 to 4, in which
the first region surrounds the vibration portion in plan view, and
the second region is located on one side or both sides of the vibration portion and the first region in the first direction in plan view and is not located on either side of the vibration portion and the first region in the second direction.

### (Concept 6)

The piezoelectric vibration element according to any one of concepts 2 to 5, in which
the piezoelectric blank includes a through-hole located between the first region and the second region and extending through the piezoelectric blank in a thickness direction of the piezoelectric blank.

### (Concept 7)

The piezoelectric vibration element according to any one of concepts 1 to 6, further including:
a second excitation electrode overlying the second surface;
a second extension electrode extended from the second excitation electrode and overlying the fourth surface;
a third extension electrode extended from the first excitation electrode in a direction different from a direction of the first extension electrode and overlying the third surface; and
a fourth extension electrode extended from the second excitation electrode in a direction different from a direction of the second extension electrode and overlying the fourth surface, in which
the fixation portion surrounds the vibration portion in plan view,
the first extension electrode includes a portion located on a first partial edge portion side of the first excitation electrode and on a second partial edge portion side of the first excitation electrode,
the second extension electrode includes a portion located on a first partial edge portion side of the second excitation electrode and on a side of the second excitation electrode opposite to the second partial edge portion,
the third extension electrode includes a portion located on a side of the first excitation electrode opposite to the first partial edge portion side and on the second partial edge portion side of the first excitation electrode, and
the fourth extension electrode includes a portion located on a side of the second excitation electrode opposite to the first partial edge portion and on the side of the second excitation electrode opposite to the second partial edge portion.

### (Concept 8)

The piezoelectric vibration element according to any one of concepts 1 to 7, in which
the first edge portion includes:
   a third partial edge portion facing the first partial edge portion with the vibration portion interposed therebetween; and
   a fourth partial edge portion facing the second partial edge portion with the vibration portion interposed therebetween, and
the piezoelectric blank includes four recesses in total including the first recess, the four recesses being located at four recessed corners formed by the first partial edge portion, the second partial edge portion, the third partial edge portion, and the fourth partial edge portion in plan view, being recessed from the third surface toward the second side, and having shapes in which the first edge portion is cut in.

### (Concept 9)

The piezoelectric vibration element according to any one of concepts 1 to 8, in which
when size of the first recess in a direction parallel to the first edge portion is referred to as width of the first recess, a side surface of the first recess intersecting the first edge portion in plan view includes an inclined surface inclined in an orientation in which the width of the first recess increases toward the first side and extending from a bottom portion of the first recess to the third surface, and
the first extension electrode includes a portion extending from the bottom portion of the first recess via the inclined surface to the third surface.

### (Concept 10)

A piezoelectric vibration element including:
a piezoelectric blank including a vibration portion and a fixation portion including different regions in plan view,
   the vibration portion including:
      a first surface facing a first side; and
      a second surface facing a second side opposite to the first side,
   the fixation portion including:
      a third surface facing the first side; and
      a fourth surface facing the second side,
   the third surface being higher than the first surface in a direction of the first side;
a first excitation electrode overlying the first surface; and
a first extension electrode extended from the first excitation electrode and overlying the third surface, in which
the piezoelectric blank includes a first recess recessed from the third surface toward the second side,
the first recess has a shape in plan view in which a first edge portion of the third surface on a first surface side is cut in,
the first extension electrode includes a portion extending from the first surface via the first recess to the third surface,
when size of the first recess in a direction parallel to the first edge portion is referred to as width of the first recess, a side surface of the first recess intersecting the first edge portion in plan view includes an inclined surface inclined in an orientation in which the width of the first recess increases toward the first side and extending from a bottom portion of the first recess to the third surface, and
the first extension electrode includes a portion extending from the bottom portion of the first recess via the inclined surface to the third surface.

### (Concept 11)

The piezoelectric vibration element according to concept 9 or 10, in which
the side surface of the first recess includes a crystal plane.

### (Concept 12)

The piezoelectric vibration element according to any one of concepts 1 to 11, in which
when size of the first recess in a direction parallel to the first edge portion is referred to as width of the first recess, the width of the first recess at height of the first edge portion is larger than thickness of the vibration portion.

### (Concept 13)

The piezoelectric vibration element according to any one of concepts 1 to 12, in which
horizontal depth of the first recess from the first edge portion in plan view at height of the first edge portion is larger than thickness of the vibration portion.

### (Concept 14)

The piezoelectric vibration element according to any one of concepts 1 to 13, in which
when size of the first recess in a direction parallel to the first edge portion is referred to as width of the first recess, the width of the first recess at height of the first edge portion is larger than height from the first surface to the first edge portion.

### (Concept 15)

The piezoelectric vibration element according to any one of concepts 1 to 14, in which
horizontal depth of the first recess from the first edge portion in plan view at height of the first edge portion is larger than height from the first surface to the first edge portion.

### (Concept 16)

The piezoelectric vibration element according to any one of concepts 1 to 15, in which
an inner surface of the first recess includes:
   a bottom surface connected to the first surface and flush with the first surface; and
   an end surface located on a side of the bottom surface opposite to the first surface in plan view, rising from the bottom surface to the first edge portion, and inclined in an orientation in which the end surface comes closer to height of the first edge portion at a position further away from the bottom surface in plan view, and
the bottom surface protrudes from the first edge portion toward a third surface side in plan view.

### (Concept 17)

The piezoelectric vibration element according to any one of concepts 1 to 16, in which
the piezoelectric blank includes a fifth surface connecting the first surface to the first edge portion and inclined in an orientation in which the fifth surface is located closer to the first edge portion at a position further toward the first side, and
when size of the first recess in a direction parallel to the first edge portion is referred to as width of the first recess, the width of the first recess at height of the first edge portion is larger than length of the fifth surface from the first surface to the first edge portion in plan view.

### (Concept 18)

The piezoelectric vibration element according to any one of concepts 1 to 17, in which
the piezoelectric blank includes a fifth surface connecting the first surface to the first edge portion and inclined in an orientation in which the fifth surface is located closer to the first edge portion at a position further toward the first side, and
horizontal depth of the first recess from the first edge portion in plan view at height of the first edge portion is larger than length of the fifth surface from the first surface to the first edge portion in plan view.

### (Concept 19)

The piezoelectric vibration element according to any one of concepts 1 to 18, in which
the first extension electrode includes:
   a wiring portion extending from the first excitation electrode; and
   a pad portion coupled to the wiring portion and wider than the wiring portion in a direction parallel to the first edge portion, and
the first recess includes a portion overlapping the wiring portion in plan view.

### (Concept 20)

A piezoelectric device including:
the piezoelectric vibration element according to any one of concepts 1 to 19; and
a package on which the piezoelectric vibration element is mounted.

### REFERENCE SIGNS

1, 601 quartz crystal element (piezoelectric vibration element)
3, 603 quartz crystal blank (piezoelectric blank)
7, 607 excitation electrode (first excitation electrode)
9, 609 extension electrode (first extension electrode)
11, 611 vibration portion
13, 613 fixation portion
15, 615A recess (first recess)
15b first side surface (side surface)
19A, 619A first surface
19B, 619B second surface
21A, 621A third surface
21B, 621B fourth surface
21a, 621a edge portion (first edge portion)
621aa partial edge portion (first to fourth partial edge portions)
101 quartz crystal device (piezoelectric device)

1. A piezoelectric vibration element comprising:
a piezoelectric blank comprising a vibration portion and a fixation portion comprising different regions in plan view,
the vibration portion comprising:
a first surface facing a first side; and
a second surface facing a second side opposite to the first side,
the fixation portion comprising:
a third surface facing the first side; and
a fourth surface facing the second side,
the third surface being higher than the first surface in a direction of the first side;
a first excitation electrode overlying the first surface; and
a first extension electrode extended from the first excitation electrode and overlying the third surface, wherein
the piezoelectric blank comprises a first recess recessed from the third surface toward the second side,
the first recess has a shape in plan view in which a first edge portion of the third surface on a first surface side is cut in,
the first extension electrode comprises a portion extending from the first surface via the first recess to the third surface,
the first edge portion comprises:
a first partial edge portion located on one side of the vibration portion in a first direction in plan view; and
a second partial edge portion located on one side of the vibration portion in a second direction orthogonal to the first direction in plan view and, along with the first partial edge portion, forming a recessed corner, and
the first recess has a shape in which at least one of the first partial edge portion and the second partial edge portion is cut in at the recessed corner.

2. The piezoelectric vibration element according to claim 1, wherein
the third surface comprises:
a first region comprising the first edge portion; and
a second region located on a side of the first region opposite to the first surface in plan view and being higher than the first region in the direction of the first side, and
the first extension electrode extends via the first region to the second region.

3. The piezoelectric vibration element according to claim 2, wherein
the piezoelectric blank comprises a second-region recess recessed from the second region toward the second side,
the second-region recess has a shape in plan view in which a second-region edge portion of the second region on a first region side is cut in, and
the first extension electrode extends from the first recess via the second-region recess to the second region.

4. The piezoelectric vibration element according to claim 2, wherein
the first extension electrode comprises:
a wiring portion extending from the first excitation electrode and passing the first recess; and
a pad portion comprising a portion overlapping the second region and being wider than the wiring portion in a direction parallel to the first edge portion.

5. The piezoelectric vibration element according to claim 2, wherein
the first region surrounds the vibration portion in plan view, and
the second region is located on one side or both sides of the vibration portion and the first region in the first direction in plan view and is not located on either side of the vibration portion and the first region in the second direction.

6. The piezoelectric vibration element according to claim 2, wherein
the piezoelectric blank comprises a through-hole located between the first region and the second region and extending through the piezoelectric blank in a thickness direction of the piezoelectric blank.

7. The piezoelectric vibration element according to claim 1, further comprising:
a second excitation electrode overlying the second surface;
a second extension electrode extended from the second excitation electrode and overlying the fourth surface;
a third extension electrode extended from the first excitation electrode in a direction different from a direction of the first extension electrode and overlying the third surface; and
a fourth extension electrode extended from the second excitation electrode in a direction different from a direction of the second extension electrode and overlying the fourth surface, wherein
the fixation portion surrounds the vibration portion in plan view,
the first extension electrode comprises a portion located on a first partial edge portion side of the first excitation electrode and on a second partial edge portion side of the first excitation electrode,
the second extension electrode comprises a portion located on a first partial edge portion side of the second excitation electrode and on a side of the second excitation electrode opposite to the second partial edge portion,
the third extension electrode comprises a portion located on a side of the first excitation electrode opposite to the first partial edge portion side and on the second partial edge portion side of the first excitation electrode, and
the fourth extension electrode comprises a portion located on a side of the second excitation electrode opposite to the first partial edge portion and on the side of the second excitation electrode opposite to the second partial edge portion.

8. The piezoelectric vibration element according to claim 1, wherein
the first edge portion comprises:
a third partial edge portion facing the first partial edge portion with the vibration portion interposed therebetween; and
a fourth partial edge portion facing the second partial edge portion with the vibration portion interposed therebetween, and
the piezoelectric blank comprises four recesses in total comprising the first recess, the four recesses being located at four recessed corners formed by the first partial edge portion, the second partial edge portion, the third partial edge portion, and the fourth partial edge portion in plan view, being recessed from the third surface toward the second side, and having shapes in which the first edge portion is cut in.

9. The piezoelectric vibration element according to claim 1, wherein
when size of the first recess in a direction parallel to the first edge portion is referred to as width of the first recess, a side surface of the first recess intersecting the first edge portion in plan view comprises an inclined surface inclined in an orientation in which the width of the first recess increases toward the first side and extending from a bottom portion of the first recess to the third surface, and
the first extension electrode comprises a portion extending from the bottom portion of the first recess via the inclined surface to the third surface.

10. A piezoelectric vibration element comprising:
a piezoelectric blank comprising a vibration portion and a fixation portion comprising different regions in plan view,
the vibration portion comprising:
a first surface facing a first side; and
a second surface facing a second side opposite to the first side,
the fixation portion comprising:
a third surface facing the first side; and
a fourth surface facing the second side,
the third surface being higher than the first surface in a direction of the first side;
a first excitation electrode overlying the first surface; and
a first extension electrode extended from the first excitation electrode and overlying the third surface, wherein
the piezoelectric blank comprises a first recess recessed from the third surface toward the second side,
the first recess has a shape in plan view in which a first edge portion of the third surface on a first surface side is cut in,
the first extension electrode comprises a portion extending from the first surface via the first recess to the third surface,
when size of the first recess in a direction parallel to the first edge portion is referred to as width of the first recess, a side surface of the first recess intersecting the first edge portion in plan view comprises an inclined surface inclined in an orientation in which the width of the first recess increases toward the first side and extending from a bottom portion of the first recess to the third surface, and
the first extension electrode comprises a portion extending from the bottom portion of the first recess via the inclined surface to the third surface.

11. The piezoelectric vibration element according to claim 9, wherein
the side surface of the first recess comprises a crystal plane.

12. The piezoelectric vibration element according to claim 1, wherein
when size of the first recess in a direction parallel to the first edge portion is referred to as width of the first recess, the width of the first recess at height of the first edge portion is larger than thickness of the vibration portion.

13. The piezoelectric vibration element according to claim 1, wherein
horizontal depth of the first recess from the first edge portion in plan view at height of the first edge portion is larger than thickness of the vibration portion.

14. The piezoelectric vibration element according to claim 1, wherein
when size of the first recess in a direction parallel to the first edge portion is referred to as width of the first recess, the width of the first recess at height of the first edge portion is larger than height from the first surface to the first edge portion.

15. The piezoelectric vibration element according to claim 1, wherein
horizontal depth of the first recess from the first edge portion in plan view at height of the first edge portion is larger than height from the first surface to the first edge portion.

16. The piezoelectric vibration element according to claim 1, wherein
an inner surface of the first recess comprises:
a bottom surface connected to the first surface and flush with the first surface; and
an end surface located on a side of the bottom surface opposite to the first surface in plan view, rising from the bottom surface to the first edge portion, and inclined in an orientation in which the end surface comes closer to height of the first edge portion at a position further away from the bottom surface in plan view, and
the bottom surface protrudes from the first edge portion toward a third surface side in plan view.

17. The piezoelectric vibration element according to claim 1, wherein
the piezoelectric blank comprises a fifth surface connecting the first surface to the first edge portion and inclined in an orientation in which the fifth surface is located closer to the first edge portion at a position further toward the first side, and
when size of the first recess in a direction parallel to the first edge portion is referred to as width of the first recess, the width of the first recess at height of the first edge portion is larger than length of the fifth surface from the first surface to the first edge portion in plan view.

18. The piezoelectric vibration element according to claim 1, wherein
the piezoelectric blank comprises a fifth surface connecting the first surface to the first edge portion and inclined in an orientation in which the fifth surface is located closer to the first edge portion at a position further toward the first side, and
horizontal depth of the first recess from the first edge portion in plan view at height of the first edge portion is larger than length of the fifth surface from the first surface to the first edge portion in plan view.

19. The piezoelectric vibration element according to claim 1, wherein
the first extension electrode comprises:
a wiring portion extending from the first excitation electrode; and
a pad portion coupled to the wiring portion and wider than the wiring portion in a direction parallel to the first edge portion, and
the first recess comprises a portion overlapping the wiring portion in plan view.

20. A piezoelectric device comprising:
the piezoelectric vibration element according to claim 1; and
a package on which the piezoelectric vibration element is mounted.
